(19) United States
(12) Patent Application Publication
(10) Pub. No.: US 2011/0290701 A1
(43) Pub. Date: Dec. 1, 2011

(54) WORKPIECE CARRIER AND WORKPIECE CARRIER LOADING/UNLOADING SYSTEM AND METHOD

(76) Inventors: Ricky P. Bennett, Flemington, NJ (US); Richard J. Lieske, Winona, MN (US); Tony Du, Fountain Valley, CA (US)

(21) Appl. No.: 12/514,652

(22) PCT Filed: Nov. 13, 2007
(86) PCT No.: PCT/GB07/04325

§ 371 Date: Jun. 10, 2011

(30) Foreign Application Priority Data
Nov. 13, 2006 (GB) 0622619.5

(51) Int. Cl. H05K 13/00; H01L 21/673

(52) U.S. Cl. 206/725

(57) ABSTRACT

A workpiece carrier for supporting a plurality of workpieces, the workpiece carrier comprising: a plurality of support elements, each for supporting a workpiece; and a plurality of positioning elements, each associated with a respective one of the support elements and being operative to position a workpiece at a predetermined position in the respective support element, wherein the positioning elements each comprise a plurality of biasing elements which are disposed in opposed relation and configured laterally to bias the workpiece and position the workpiece at the predetermined position.

The present invention relates to a workpiece carrier for supporting a plurality of workpieces, and a workpiece carrier loading/unloading system and method for loading and unloading workpieces into and from such a workpiece carrier.

The continuous development of electronics is resulting in more complex systems being contained in smaller components, leading to the use of smaller printed circuit boards. One example is the mobile telephone, where progressively smaller mobile telephones are being developed which have at least the same, if not increased, functionality.

Traditionally, in handling small printed circuit boards, the practice was to fabricate the printed circuit boards as an array of separable panels in a single, large board, thereby allowing the printed circuit boards to be handled as a single entity. This approach has been used successfully, but the increased accuracy required by the newer, smaller components cannot be achieved by this technique. As a result, such small printed circuit boards have again to be handled separately.

In addition, larger electronic components are being developed as increased functionality is integrated into a single integrated circuit and more than one integrated circuit plus resistors and capacitors are assembled onto a substrate, such as a ball grid array (BGA) substrate or a pin grid array (PGA) substrate, to form a single component. These larger electronic components have also to be handled separately.

For handling such workpieces, workpiece carriers have been developed which allow a plurality of workpieces to be transported simultaneously to a machine, such as a screen printing machine or a placement machine, for operation by the machine. Such workpiece carriers include those manufactured to the JEDEC (Joint Electron Device Engineering Council) standard.

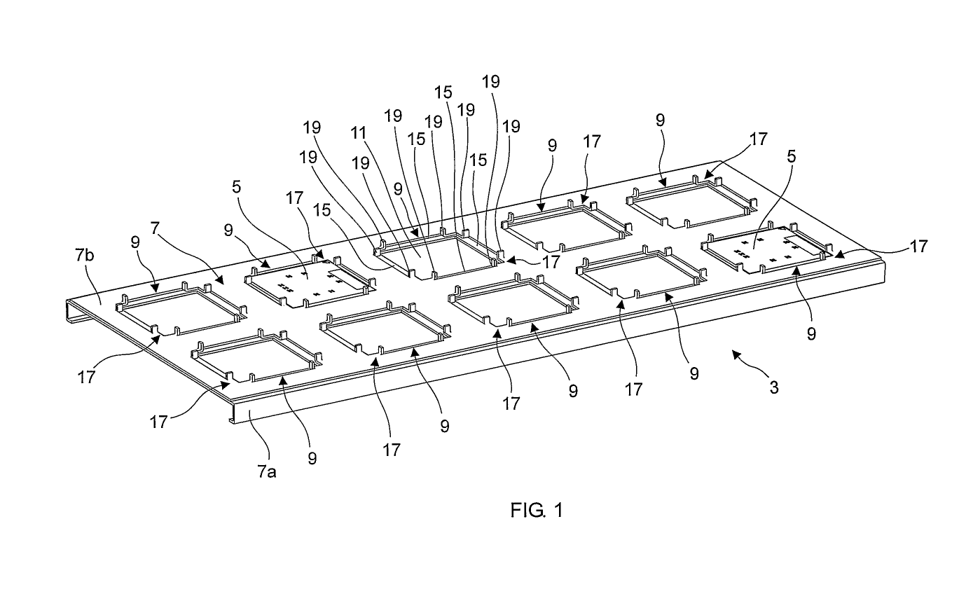

FIG. 1 illustrates one such workpiece carrier 3 which is used to support a plurality of workpieces 5 in transporting the same to a machine for operation. For the purposes of illustration, the workpiece carrier 3 is illustrated only partially filled with workpieces 5.

The workpiece carrier 3 comprises a plate 7 which includes a plurality of support elements 9, in this embodiment ten support elements 9 arranged in pairs in a 2×5 array, for supporting respective ones of the workpieces 5.

The plate 7 comprises lower and upper plate parts 7a, 7b which are fixed together by suitable means, such as by bonding, spot welding and riveting.

The support elements 9 each comprise a through aperture 11, in this embodiment a square aperture, and a plurality of support members 15 which are disposed about the periphery of the aperture 11, in this embodiment four support members 15 which are located at respective ones of the sides of the aperture 11, for supporting the respective edges of a workpiece 5. The support members 15 of each support element 9 are spaced from the upper surface of the plate 7 such as to define a recess for receiving a workpiece 5, whereby the upper surface of a workpiece 5, when supported by the respective support element 9, is substantially co-planar with the upper surface of the plate 7.

The workpiece carrier 3 further comprises a plurality of workpiece-retaining elements 17, in this embodiment each comprising a plurality of pillars 19, for retaining workpieces 5 in the respective ones of the support elements 9. In this embodiment the workpiece-retaining elements 17 each comprise eight pillars 19, each pillar 19 being located adjacent a respective corner of the respective support element 9, such as to retain a workpiece 5 captive therewithin.

Typically, in the fabrication of an electronic device, a viscous solder paste is first applied to selected areas of a workpiece, such as a substrate, for example, a printed circuit board, through a stencil in a screen printing machine. Electronic components are then placed on the applied solder paste using a placement machine, often referred to as a pick-and-place machine. The workpiece and components are then heated in a re-flow oven to a temperature sufficient to melt the solder paste, causing the solder paste to flow under leads of the components and corresponding pads of the workpiece, thereby forming solder joints and completing the electronic device.

The use of a workpiece carrier enables a plurality of workpieces to be transported simultaneously to a machine, thereby providing for transport efficiencies, but, where the workpieces are only roughly positioned on the workpiece carrier, each workpiece has to be handled individually in operation by the machine in order to establish the position of the supported workpiece. For example, in a screen printing machine, the workpieces are successively supported by a single vacuum tower and the stencil successively positioned by an X-Y table above each workpiece as supported by the vacuum tower, with each workpiece, when so positioned, being subject to a separate printing operation. As will be appreciated, such repeated re-positioning of the stencil for each supported workpiece is particularly time consuming, as is the requirement to print each workpiece individually. In a placement machine, for example, the workpieces are successively supported by a single vacuum tower and the robotic pick-and-place arm is re-referenced to the position of the workpiece. Again, such referencing of the pick-and-place robotic arm for each supported workpiece is time consuming.

As disclosed in WO-A-2002/089551, the present applicant has previously developed a tooling fixture which allows for the simultaneous, individual positioning of a plurality of workpieces as supported by such mentioned workpiece carriers, thereby enabling a single operation of a machine without any re-positioning or re-referencing. For example, in a screen printing machine, the tooling fixture allows for the printing of a plurality of workpieces in a single printing operation without any re-positioning of the stencil. In a placement machine, for example, the tooling fixture allows for the placement of components on a plurality of workpieces in a single operation without any re-referencing of the pick-and-place robotic arm.

It is an aim of the present invention to provide an improved workpiece carrier which automatically provides for the precise individual positioning of a plurality of workpieces when loaded thereon and does not require any subsequent positioning operations to align the workpieces to the workpiece carrier.

In one aspect the present invention provides a workpiece carrier for supporting a plurality of workpieces, the workpiece carrier comprising: a plurality of support elements, each for supporting a workpiece; and a plurality of positioning elements, each associated with a respective one of the support elements and being operative to position a workpiece at a predetermined position in the respective support element, wherein the positioning elements each comprise a plurality of biasing elements which are disposed in opposed relation and configured laterally to bias the workpiece and position the workpiece at the predetermined position.

In another aspect the present invention provides a workpiece carrier loading/unloading system, comprising: the above-described workpiece carrier; and a workpiece loading/unloading assembly for loading and unloading workpieces into and from the support elements of the workpiece carrier.

In a further aspect the present invention provides a workpiece carrier loading/unloading system, comprising: a workpiece carrier for supporting a plurality of workpieces, the workpiece carrier comprising: a plurality of support elements, each for supporting a workpiece; and a plurality of positioning elements, each associated with a respective one of the support elements and being operative to position a workpiece at a predetermined position in the respective support element, wherein the positioning elements each comprise a plurality of biasing elements which are disposed in opposed relation and configured laterally to bias the workpiece and position the workpiece at the predetermined position; and a workpiece loading/unloading assembly for loading and unloading workpieces into and from the support elements of the workpiece carrier.

In a still further aspect the present invention provides a method of loading workpieces into a workpiece carrier, comprising the steps of: providing a workpiece carrier for supporting a plurality of workpieces, the workpiece carrier comprising: a plurality of support elements, each for supporting a workpiece; and a plurality of positioning elements, each associated with a respective one of the support elements and being operative to position a workpiece at a predetermined position in the respective support element, wherein the positioning elements each comprise a plurality of biasing elements which are disposed in opposed relation and configured laterally to bias the workpiece and position the workpiece at the predetermined position; providing a workpiece loading assembly for loading workpieces into the support elements of the workpiece carrier; and utilizing the workpiece loading assembly to load workpieces into the workpiece carrier.

In a yet still further aspect the present invention provides a method of unloading workpieces from a workpiece carrier, comprising the steps of: providing a workpiece carrier for supporting a plurality of workpieces, the workpiece carrier comprising: a plurality of support elements, each for supporting a workpiece; and a plurality of positioning elements, each associated with a respective one of the support elements and being operative to position a workpiece at a predetermined position in the respective support element, wherein the positioning elements each comprise a plurality of biasing elements which are disposed in opposed relation and configured laterally to bias the workpiece and position the workpiece at the predetermined position; providing a workpiece unloading assembly for unloading workpieces from the support elements of the workpiece carrier; and utilizing the workpiece unloading assembly to unload workpieces from the workpiece carrier.

Preferred embodiments of the present invention will now be described hereinbelow by way of example only with reference to the accompanying drawings, in which:

FIG. 1 illustrates a perspective view of a prior art workpiece carrier for supporting a plurality of workpieces, as illustrated partially filled with workpieces;

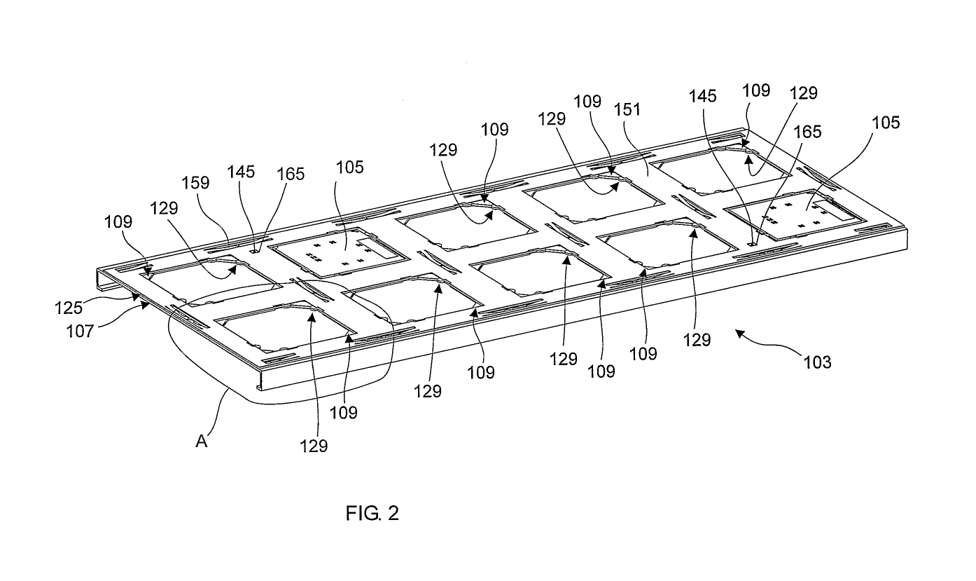

FIG. 2 illustrates a perspective view of a workpiece carrier in accordance with a first embodiment of the present invention, as illustrated partially filled with workpieces;

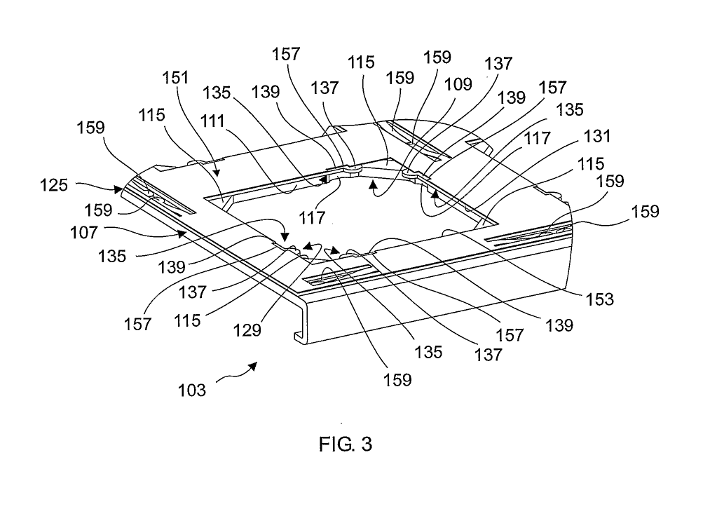

FIG. 3 illustrates in enlarged scale a fragmentary perspective view (region A in FIG. 2) of the workpiece carrier of FIG. 2;

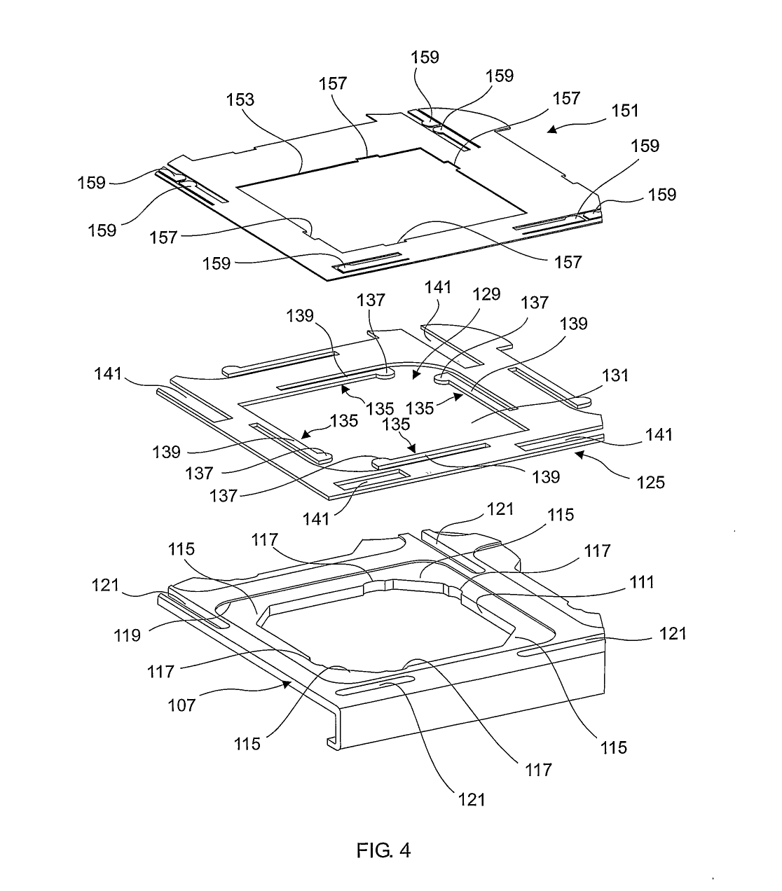

FIG. 4 illustrates an exploded perspective view of the workpiece carrier of FIG. 3;

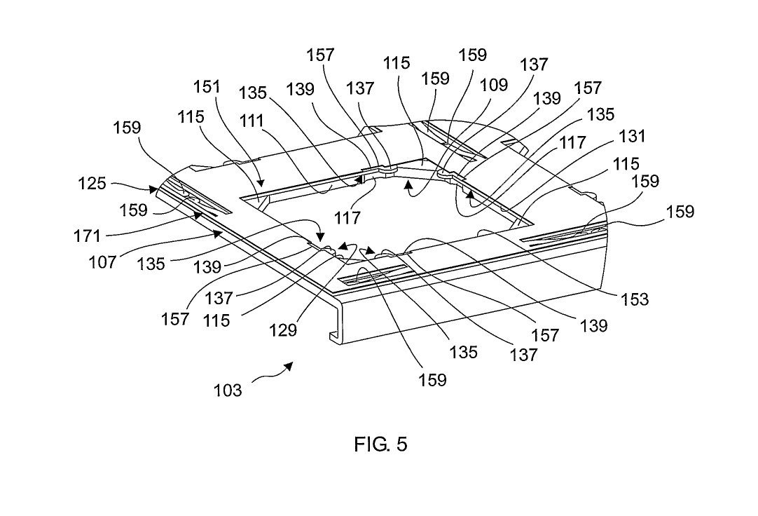

FIG. 5 illustrates in enlarged scale a fragmentary perspective view (region A in FIG. 2) of a workpiece carrier in accordance with a second embodiment of the present invention, as a modification of the workpiece carrier of FIG. 2;

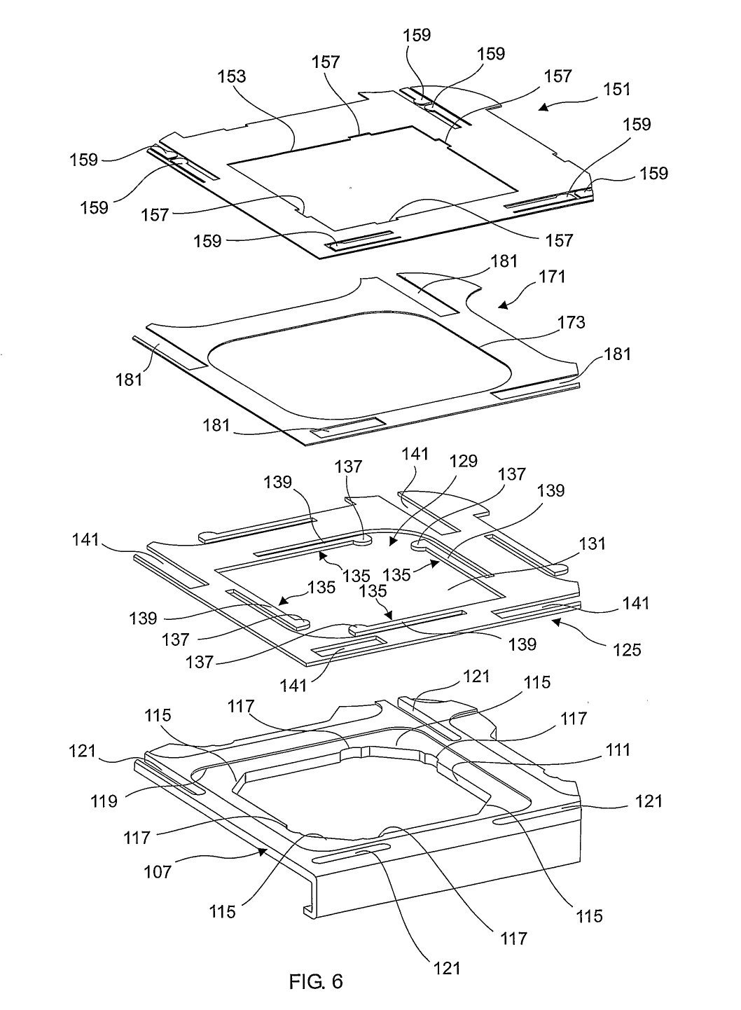

FIG. 6 illustrates an exploded perspective view of the workpiece carrier of FIG. 5;

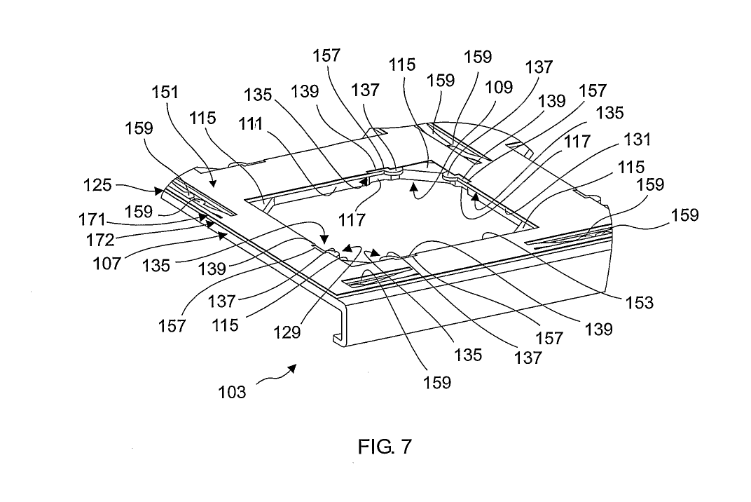

FIG. 7 illustrates in enlarged scale a fragmentary perspective view (region A in FIG. 2) of a workpiece carrier in accordance with a third embodiment of the present invention, as another modification of the workpiece carrier of FIG. 2;

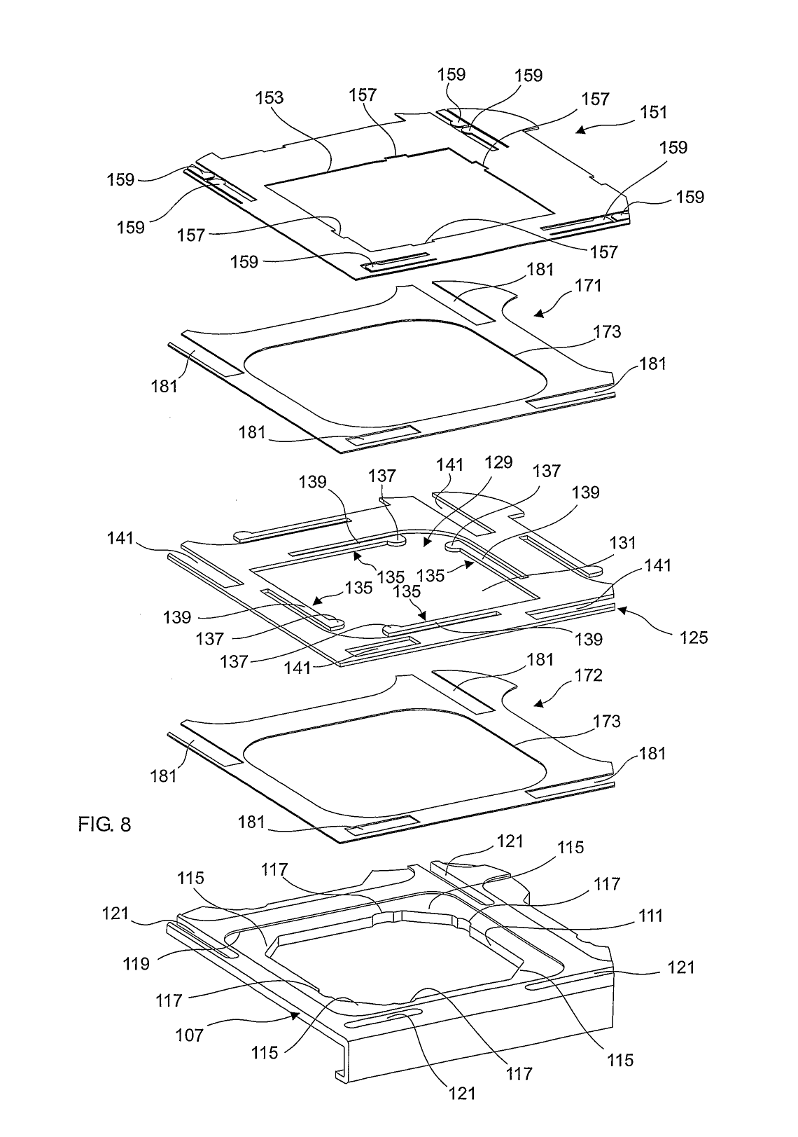

FIG. 8 illustrates an exploded perspective view of the workpiece carrier of FIG. 7;

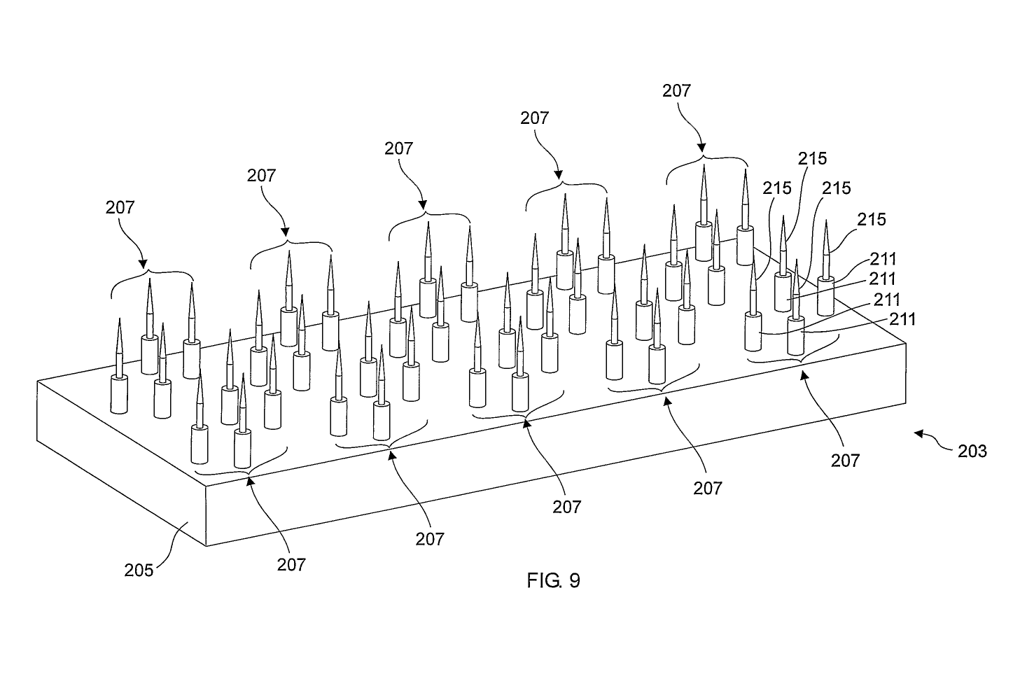

FIG. 9 illustrates a workpiece carrier loading/unloading system in accordance with a first embodiment of the present invention;

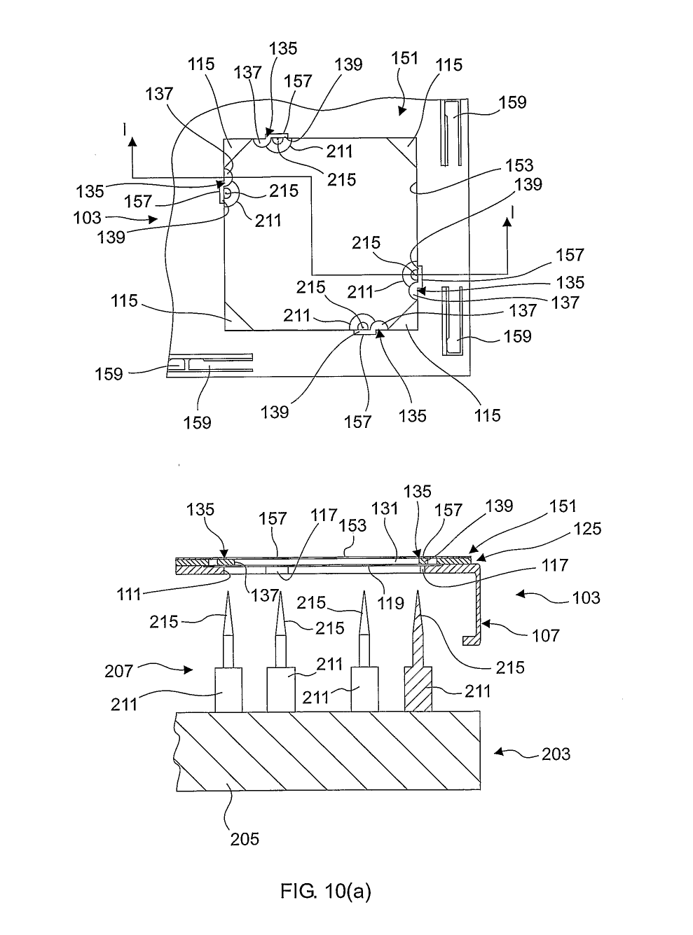

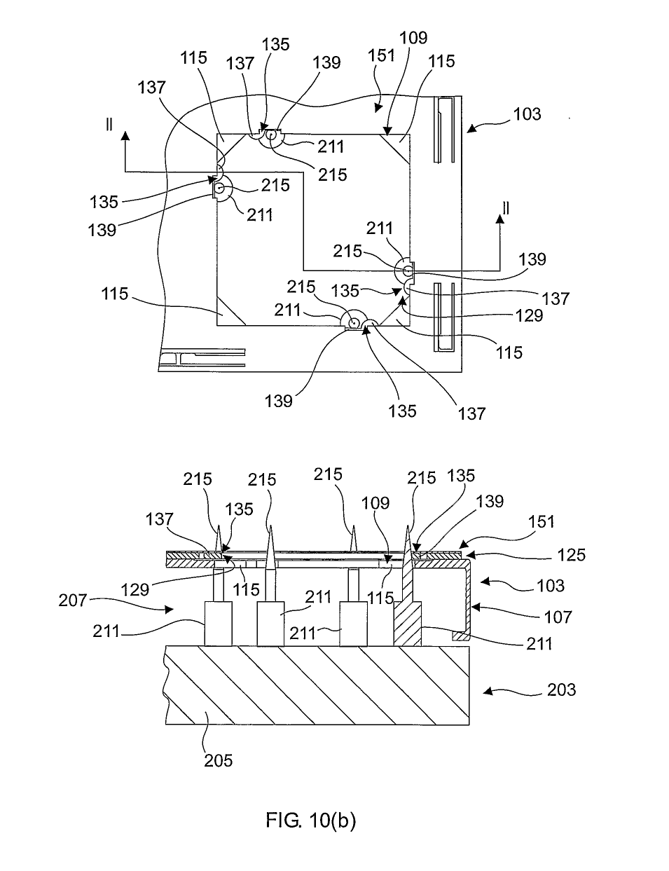

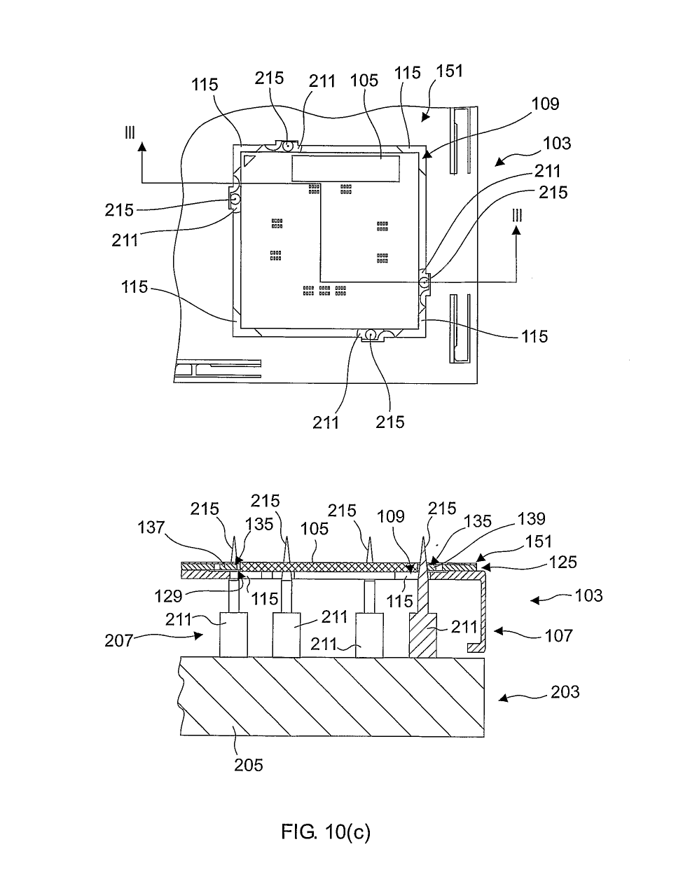

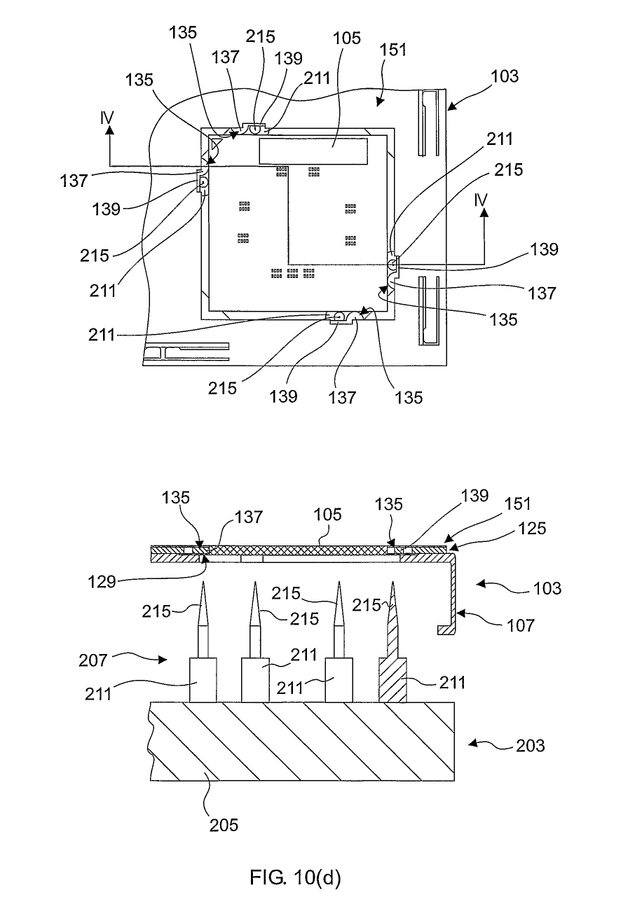

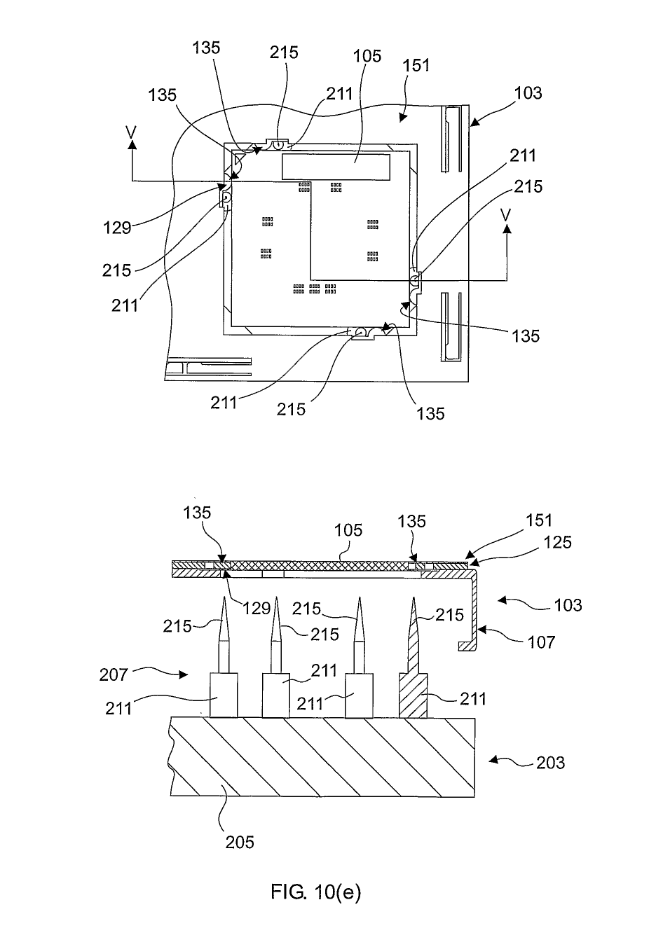

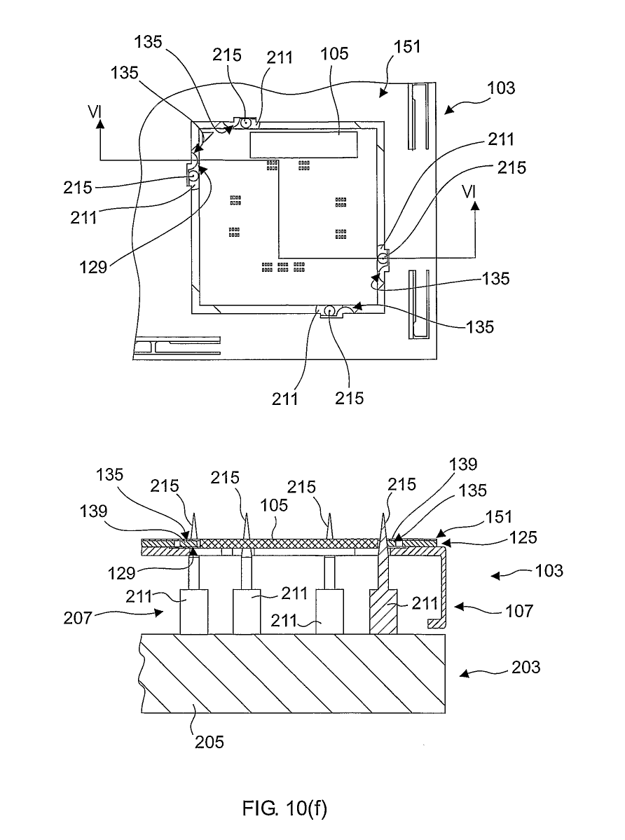

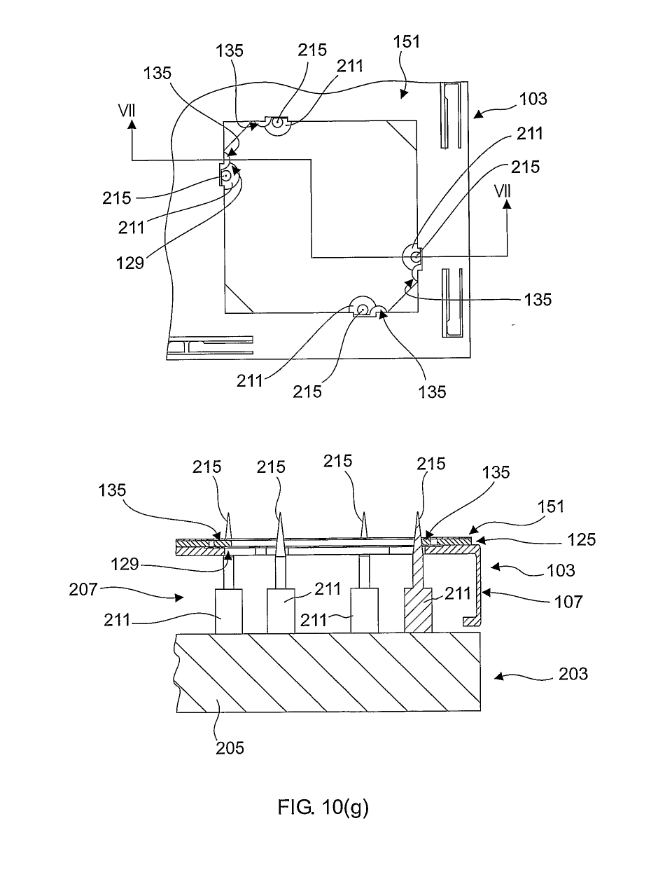

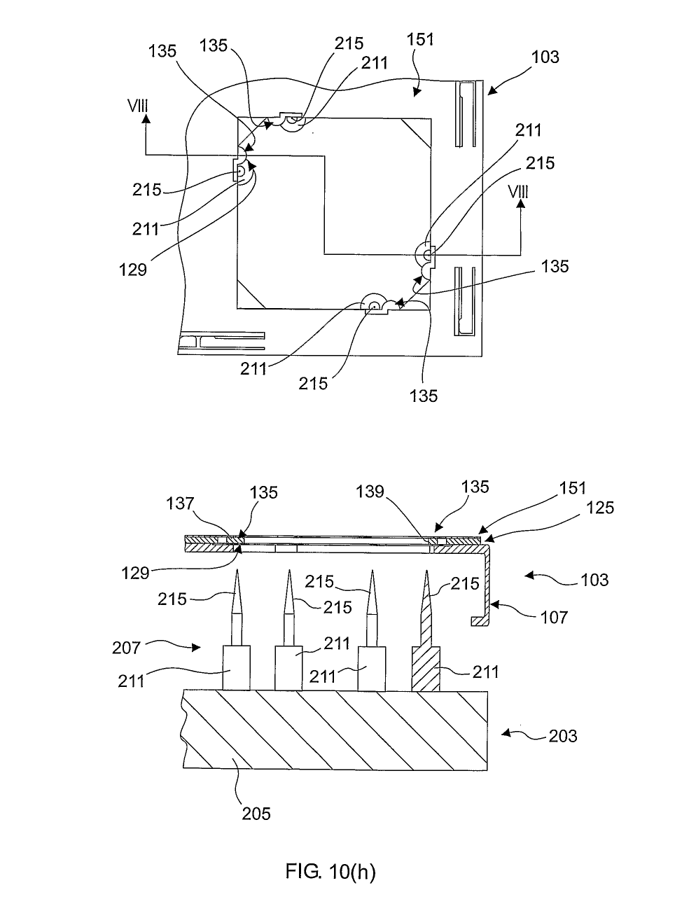

FIGS. 10(a) to (d) illustrate fragmentary plan and sectional views of the steps in a loading operation in loading workpieces into a workpiece carrier of the first to third embodiments where utilizing the workpiece carrier loading/unloading system of FIG. 9;

FIGS. 10(e) to (h) illustrate fragmentary plan and sectional views of the steps in an unloading operation in unloading workpieces from a workpiece carrier of the first to third embodiments where utilizing the workpiece carrier loading/unloading system of FIG. 9;

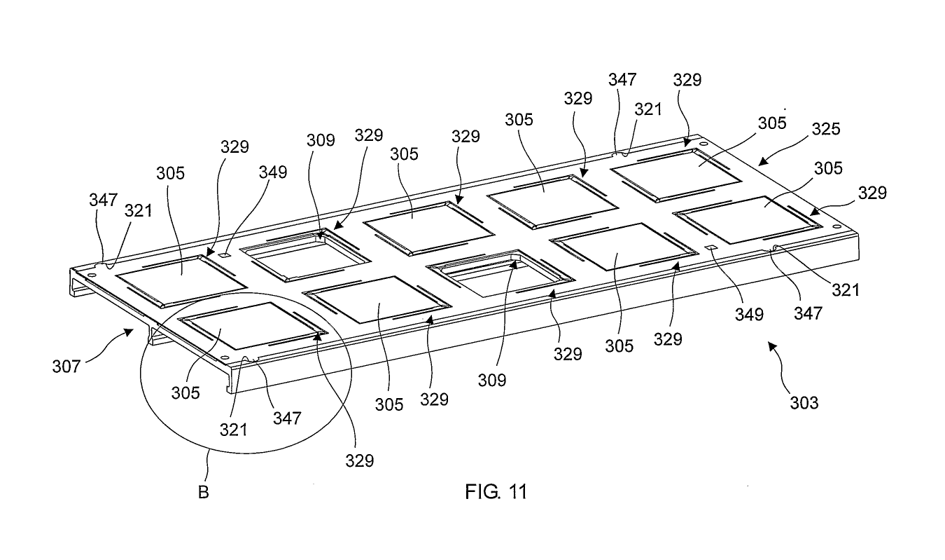

FIG. 11 illustrates a perspective view of a workpiece carrier in accordance with a fourth embodiment of the present invention, as illustrated partially filled with workpieces;

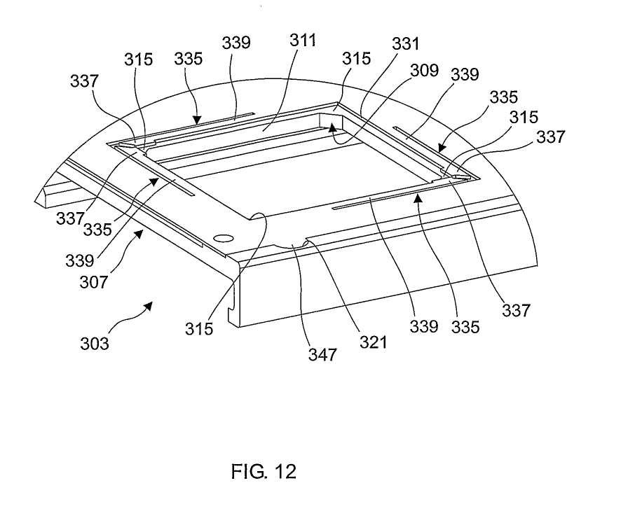

FIG. 12 illustrates in enlarged scale a fragmentary perspective view (region B in FIG. 11) of the workpiece carrier of FIG. 11;

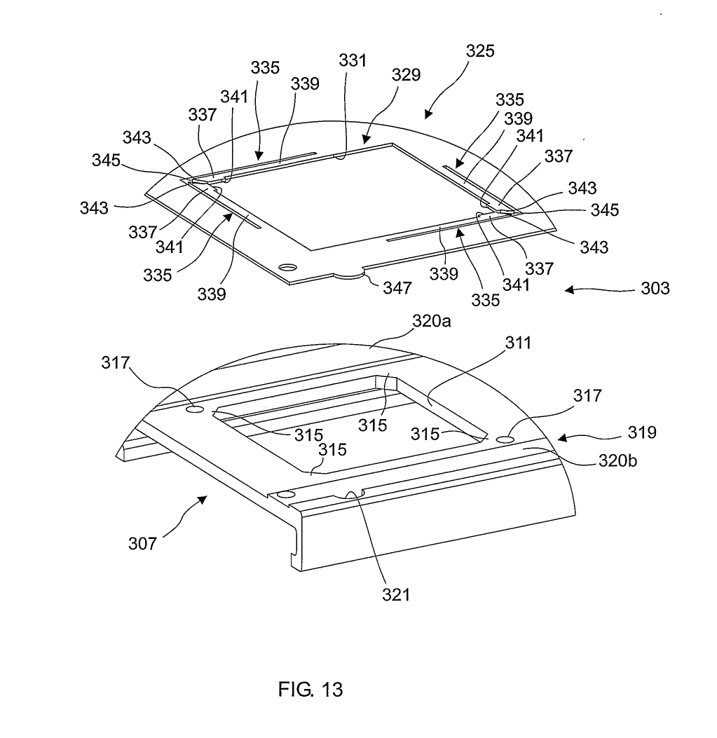

FIG. 13 illustrates an exploded perspective view of the workpiece carrier of FIG. 12;

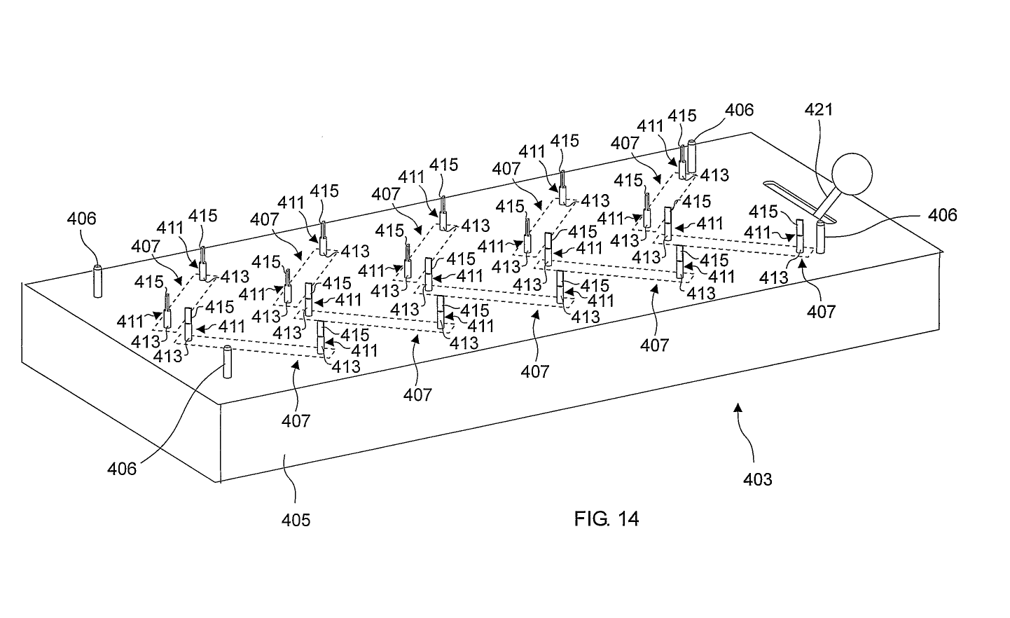

FIG. 14 illustrates a workpiece carrier loading/unloading system in accordance with a second embodiment of the present invention;

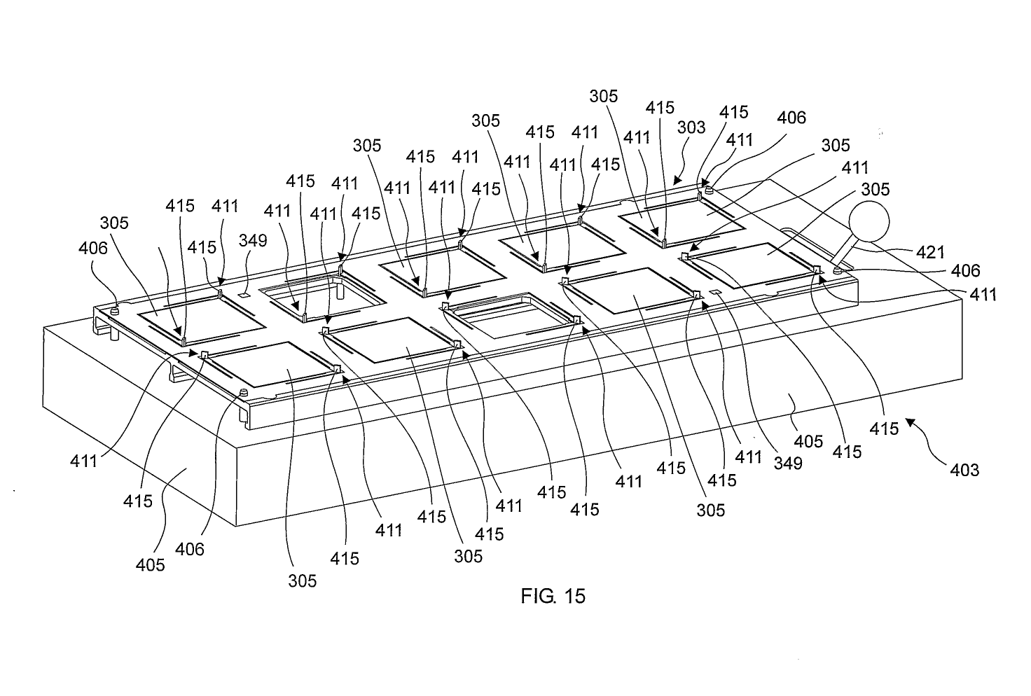

FIG. 15 illustrates the workpiece carrier loading/unloading system of FIG. 14 with the workpiece carrier of FIG. 11 loaded thereon;

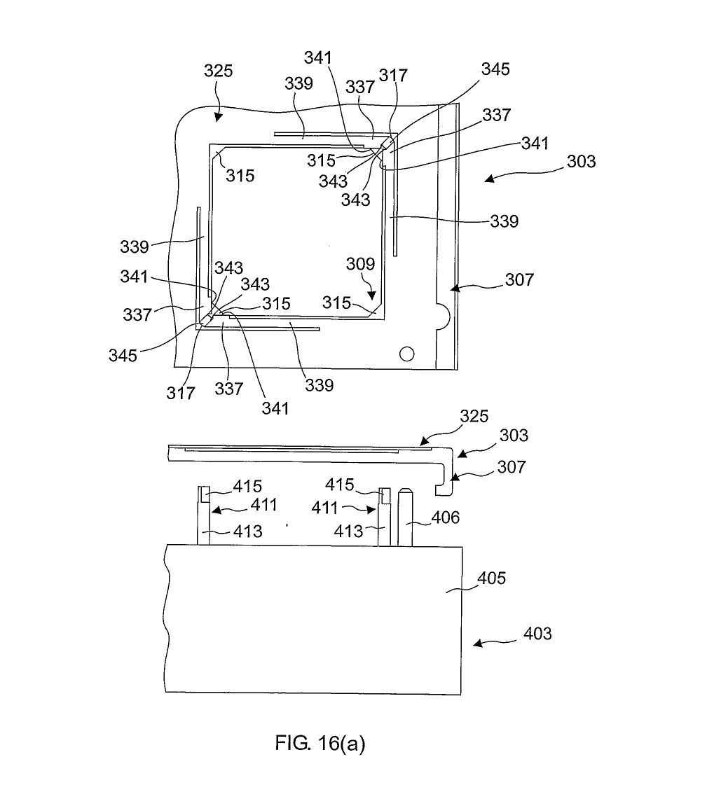

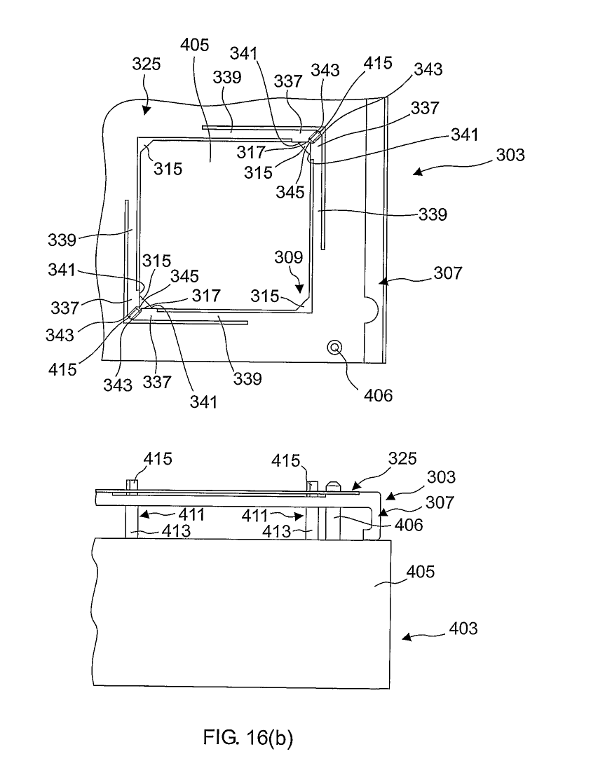

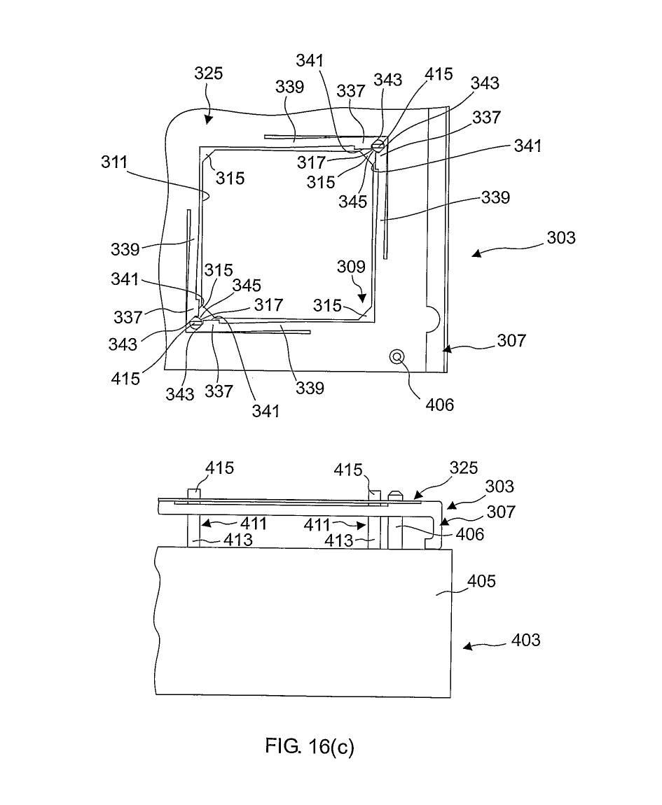

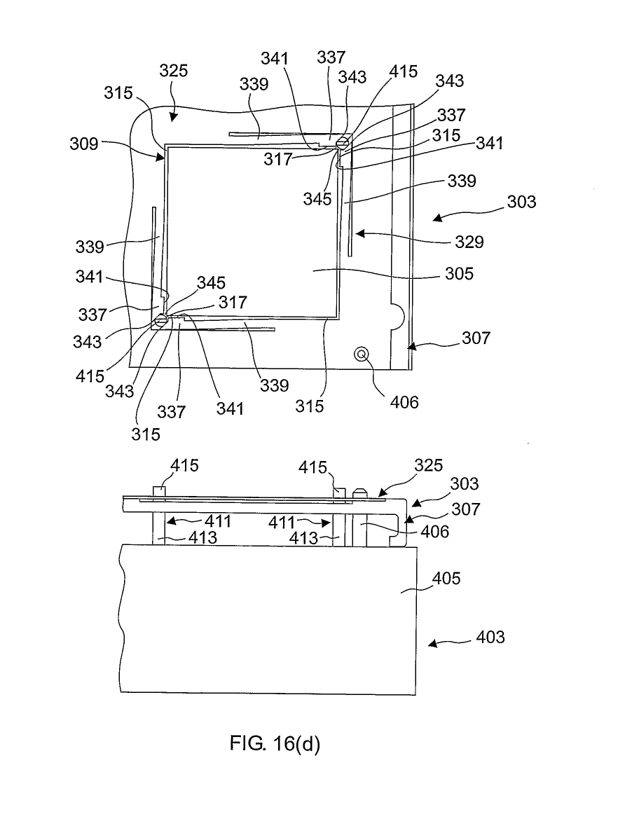

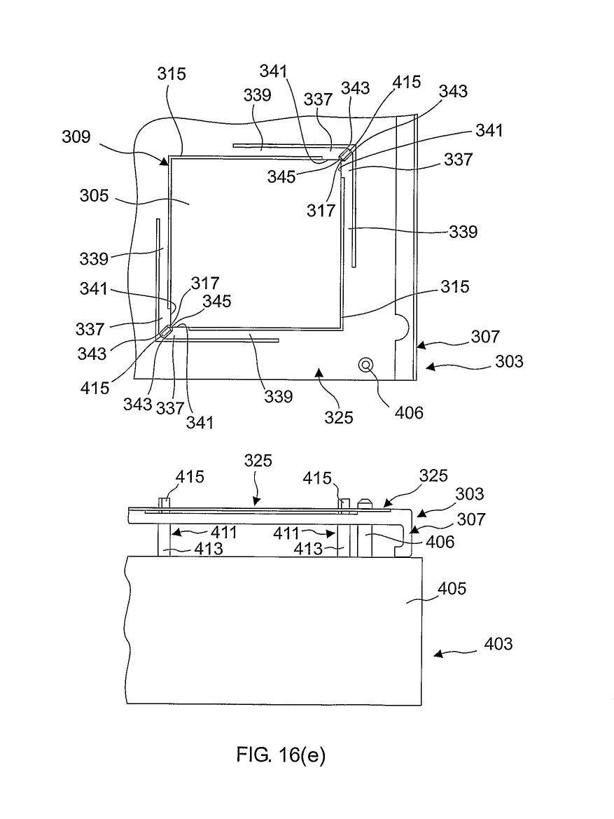

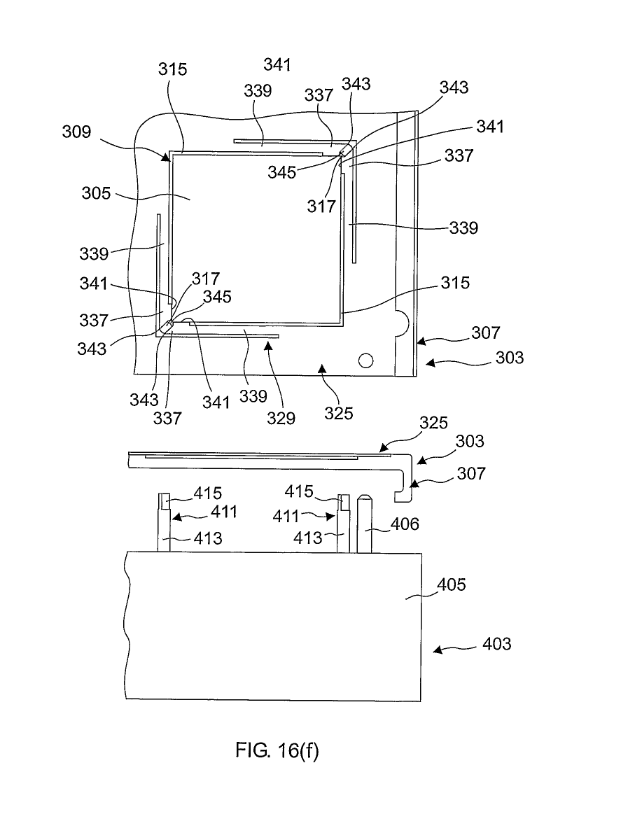

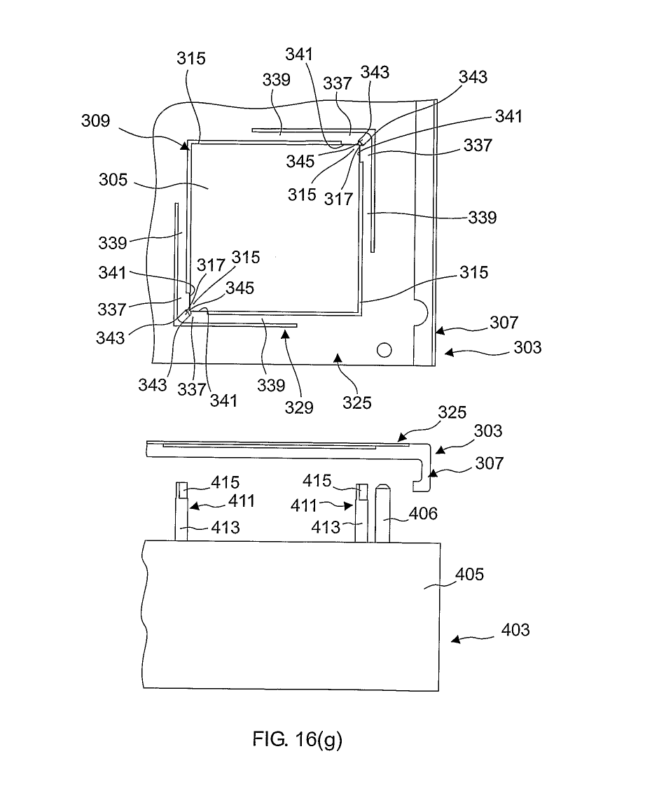

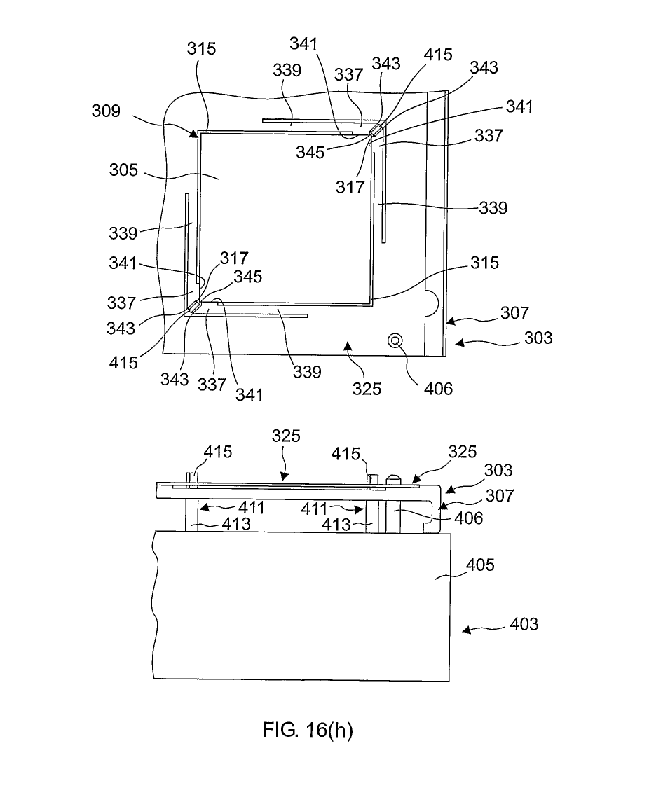

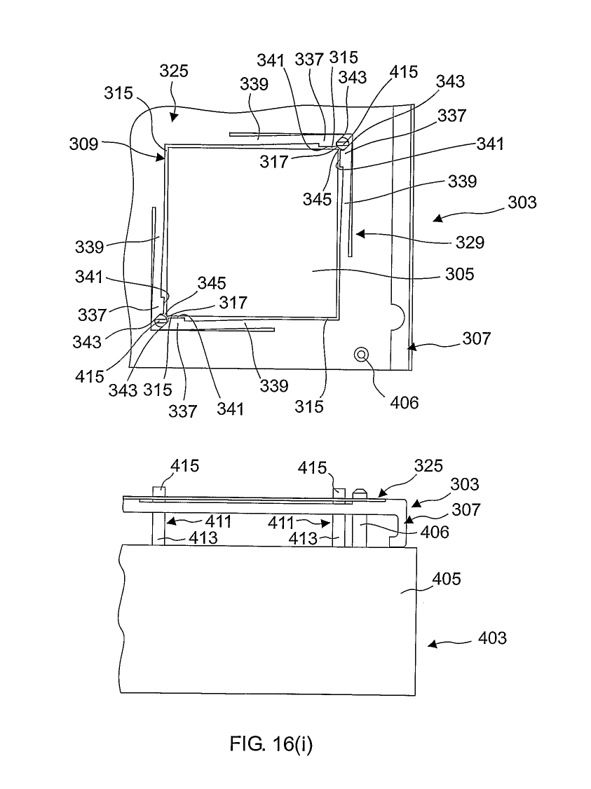

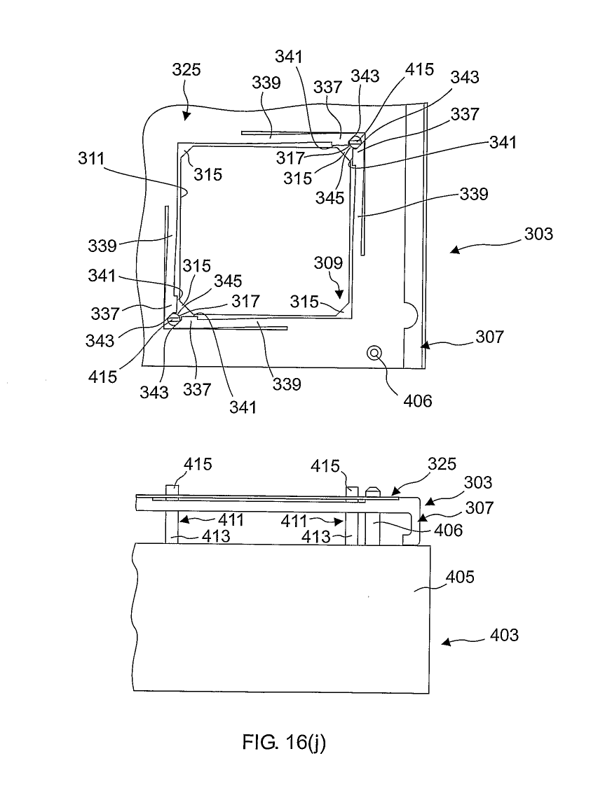

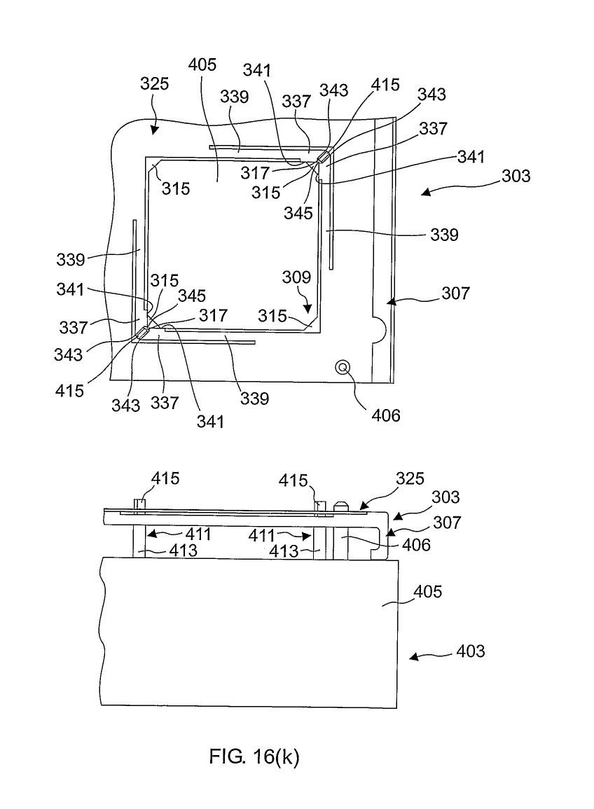

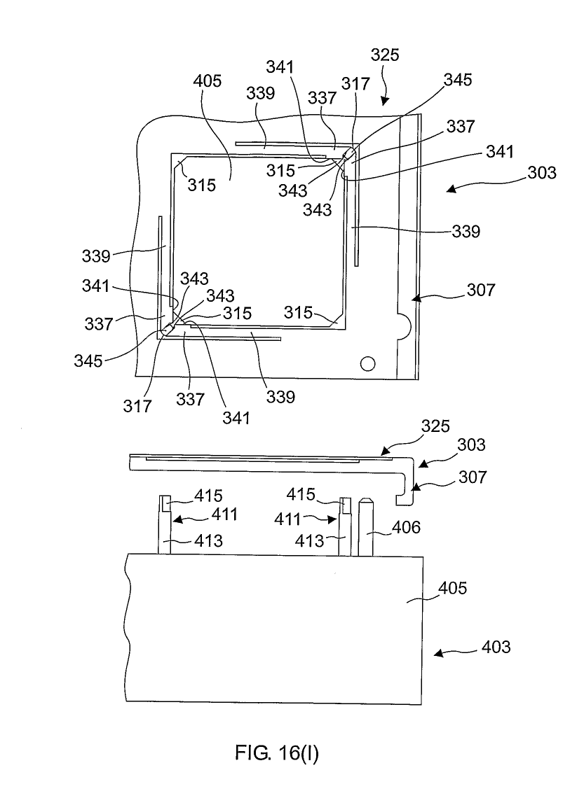

FIGS. 16(a) to (f) illustrate fragmentary plan and end views of the steps in a loading operation in loading workpieces into a workpiece carrier of the fourth embodiment where utilizing the workpiece carrier loading/unloading system of FIG. 14; and

FIGS. 16(g) to (l) illustrate fragmentary plan and end views of the steps in an unloading operation in unloading workpieces from a workpiece carrier of the fourth embodiment where utilizing the workpiece carrier loading/unloading system of FIG. 14.

FIGS. 2 to 4 illustrate a workpiece carrier 103 in accordance with a first embodiment of the present invention which provides for the precise and automatic individual positioning of a plurality of workpieces 105 when loaded thereon, without requiring any subsequent positioning operations, typically to enable operation by a machine, such as a printing, deposition or placement machine.

For the purposes of illustration, the workpiece carrier 103 is illustrated only partially filled with workpieces 105. Examples of workpieces 105 include the bases of packages, such as ball grid array (BGA) and pin grid array (PGA) substrates, which house integrated circuits, such as microprocessors, and substrates, such as printed circuit boards, onto which electronic components are mounted.

The workpiece carrier 103 comprises a lower, support member 107, in this embodiment a plate, which includes a plurality of workpiece support elements 109, in this embodiment ten support elements 109 arranged in pairs in a 2×5 array, for supporting respective ones of the workpieces 105. In other embodiments the support member 107 could include any number of support elements 109, which could be arranged in any configuration and have any shape.

The support elements 109 each comprise a through aperture 111, in this embodiment a substantially square aperture, and a plurality of workpiece supports 115 which are disposed about the periphery of the aperture 111, in this embodiment four workpiece supports 115 which are disposed at the respective corners of the aperture 111, here integrally formed at the respective corners of the aperture 111, for supporting the respective corners of a workpiece 105.

Each of the through apertures 111 includes a plurality of passages 117, in this embodiment cut-outs, which are located at the respective sides thereof, in this embodiment four passages 117 which are located in two pairs adjacent the respective corners of one pair of diagonally-opposite corners of the aperture 111. As will be described in more detail hereinbelow, the passages 117 allow for the introduction of tooling in order to effect the loading and unloading of a workpiece 105 into and from the support element 109.

The support elements 109 each further comprise a recess 119 which surrounds the upper edge of the aperture 111, such that a positioning member 125, which, as will be described in more detail hereinbelow, is disposed above the support member 107, is spaced from the support member 107 about the aperture 111.

The support member 107 further comprises a plurality of engagement slots 121 which are disposed at spaced locations over the surface thereof. As will be described in more detail hereinbelow, the engagement slots 121 receive fixing clips 159 which are formed in a cover member 151 which overlies the positioning member 125 and act to hold together the support member 107, the positioning member 125 and the cover member 151 as a unitary structure.

The workpiece carrier 103 further comprises a positioning member 125, in this embodiment formed of a sheet body, which is disposed above the support member 107 and includes a plurality of positioning elements 129, in this embodiment ten positioning elements 129 arranged in pairs in a 2×5 array and having the same configuration as the support elements 109 of the support member 107, which act automatically, precisely and individually to position respective ones of the workpieces 105 in relation to the respective support elements 109. In other embodiments the positioning member 125 could include any number of positioning elements 129, where having the same configuration and shape as the support elements 109 of the support member 107.

The positioning elements 129 each comprise a through aperture 131, in this embodiment a substantially square aperture, which has the same shape as the aperture 111 of the respective support element 109, and a plurality of spring elements 135 which are disposed about the periphery of the aperture 131 such as laterally to engage a workpiece 105, in this embodiment four spring elements 135 which are configured to engage a workpiece 105 at two pairs of locations adjacent the respective corners of the one pair of diagonally-opposite corners of the aperture 111 of the respective support element 109, such as to provide for the automatic positioning of a workpiece 105 when loaded onto the support element 109 of the support member 107.

In this embodiment the spring elements 135 each comprise a spring contact 137, here having an arcuate contact face, which laterally engages a respective side of the workpiece 105, in this embodiment adjacent a respective one of a pair of diagonally-opposite corners of the workpiece 105, and a resilient arm 139 which resiliently connects the spring contact 137 to the body of the positioning member 125, such as to bias the spring contact 137 inwardly relative to the aperture 131 of the positioning element 129.

In this embodiment each resilient arm 139 extends from a location adjacent the adjacent corner of the aperture 131 of the positioning element 129 to which the respective spring contact 137 is disposed and substantially parallel to the respective side of the aperture 131.

With this configuration, the spring elements 135 are deflectable outwardly relative to the aperture 131 of the respective positioning element 129 by tooling, as will be described in more detail hereinbelow, to allow for the loading of a workpiece 105 onto the positioning element 129, and, on removal of the tooling, the resilience of the arms 139 acts to bias the spring contacts 137 inwardly, such as automatically and individually precisely to position the loaded workpiece 105, without requiring any subsequent positioning operation.

The positioning member 125 further comprises a plurality of through slots 141 which are disposed at spaced locations over the surface thereof in correspondence to the engagement slots 121 in the support member 107. As will be described in more detail hereinbelow, the through slots 141 allow for fixing clips 159 which are formed in the cover member 151, which overlies the positioning member 125, to pass through to the support member 107, where the fixing clips 159 act to fix the position of the positioning member 125 relative to the support member 107 and hold together the support member 107, the positioning member 125 and the cover member 151 as a unitary structure.

In this embodiment the spring elements 135 are precision formed, typically by laser cutting or chemical milling, such as to have a precise and predetermined spatial arrangement, and also to ensure that the spring force of the spring elements 135 is matched, such as to ensure that the workpieces 105 are precisely positioned.

In this embodiment the sheet body of the positioning member 125 is formed of a spring steel, but could be formed of any other material which provides the spring elements 135 with the necessary characteristics which provide for the repeated accurate positioning of the supported workpieces 105.

The positioning member 125 further comprises at least two fiducials 145, which enable the alignment of the workpiece carrier 103 when mounted in a machine. As the workpieces 105 which are mounted in the workpiece carrier 103 are automatically and individually pre-positioned by the respective positioning elements 129, it is only necessary to align the workpiece carrier 103.

The workpiece carrier 103 further comprises an upper, cover member 151 which overlies the positioning member 125, and, together with the support member 107 and the positioning member 125, provides an integral unitary carrier structure.

The cover member 151, in this embodiment formed from a sheet body, comprises a plurality of through apertures 153, in this embodiment ten apertures 153 arranged in pairs in a 2×5 array in the same manner as the apertures 111 of the support elements 109 in the support member 107, which allow for workpieces 105 to be loaded into the support elements 109 of the support member 107. In other embodiments the cover member 151 could include any number of apertures 153, where having the same configuration and shape as the apertures 111 of the support elements 109 of the support member 107.

The through apertures 153 each include a plurality of passages 157, in this embodiment cut-outs, at the respective sides thereof, in this embodiment four passages 157 which are located in two pairs adjacent the respective corners of one pair of diagonally-opposite corners of the aperture 153 and coincide with the passages 117 in the respective sides of the aperture 111 of the respective support element 109 of the support member 107. As will be described in more detail hereinbelow, the passages 157 allow for the introduction of tooling in order to effect the loading and unloading of a workpiece 105 into and from a respective support element 109.

In this embodiment the cover member 151, the support member 107 and the positioning member 125 are configured such that the upper surfaces of the workpieces 105 when loaded onto the support elements 109 of the support member 107 are substantially co-planar with the upper surface of the cover member 151.

The cover member 151 further comprises a plurality of fixing clips 159, in this embodiment snap clips, which are disposed at spaced locations therein in correspondence to the through slots 141 in the positioning member 125 and the engagement slots 121 in the support member 107, and act to engage the engagement slots 121 in the support member 107, such as to hold together the support member 107, the positioning member 125 and the cover member 151 as a unitary structure and also fix the position of the positioning member 125 relative to the support member 107.

In this embodiment the use of fixing clips 159 as the means of fixing together the components of the workpiece carrier 103 advantageously allows for quick and easy assembly and dis-assembly, in the event that modification or repair is required. In other embodiments, other means of fixing could be employed, such as adhesive bonding, spot-welding and riveting.

The cover member 151 further comprises at least two fiducial apertures 165 which coincide with the at least two fiducials 145 on the positioning member 125, and provide for inspection of the at least two fiducials 145 on the positioning member 125 when aligning the workpiece carrier 103 in a machine.

FIGS. 5 and 6 illustrate a workpiece carrier in accordance with a second embodiment of the present invention.

The workpiece carrier 103 of this embodiment is quite similar to the workpiece carrier 103 of the above-described first embodiment, and thus, in order to avoid unnecessary duplication of description, only the differences will be described in detail, with like reference signs designating like parts.

The workpiece carrier 103 of this embodiment differs from that of the above-described first embodiment in further comprising a shim member 171 which is disposed between the positioning member 125 and the cover member 151, which acts to space the spring elements 135 of the positioning elements 129 from the cover member 151 and thereby facilitate movement of the spring elements 135.

The shim member 171, in this embodiment formed from a sheet body, here a stainless steel sheet, comprises a plurality of through apertures 173, in this embodiment ten apertures 173 arranged in pairs in a 2×5 array in the same manner as the apertures 111 of the support elements 109 of the support member 107, which allow for workpieces 105 to be loaded into the support elements 109 of the support member 107. The apertures 173 have a slightly larger dimension than the apertures 111 of the support elements 109, such as to extend laterally beyond the spring elements 135 of the positioning elements 129. In other embodiments the shim member 171 could include any number of apertures 173, where having the same configuration as the apertures 111 of the support elements 109 of the support member 107.

In this embodiment the shim member 171, the support member 107, the positioning member 125 and the cover member 151 are configured such that the upper surfaces of the workpieces 105 when loaded onto the support elements 109 of the support member 107 are substantially co-planar with the upper surface of the cover member 151.

The shim member 171 further comprises a plurality of through slots 181 which are disposed at spaced locations over the surface thereof in correspondence to the engagement slots 121 in the support member 107. The through slots 181 allow for the fixing clips 159 in the cover member 151, which overlies the shim member 171, to pass through to the support member 107, where the fixing clips 159 act to fix the position of the shim member 171 relative to the support member 107 and hold together the support member 107, the positioning member 125, the shim member 171 and the cover member 151 as a unitary structure.

The shim member 171 further comprises at least two fiducial apertures (not illustrated) which coincide with the at least two fiducials 145 on the positioning member 125, and provide for inspection of the at least two fiducials 145 on the positioning member 125 when aligning the workpiece carrier 103 in a machine.

FIGS. 7 and 8 illustrate a workpiece carrier in accordance with a third embodiment of the present invention.

The workpiece carrier 103 of this embodiment is quite similar to the workpiece carrier 103 of the above-described first embodiment, and thus, in order to avoid unnecessary duplication of description, only the differences will be described in detail, with like reference signs designating like parts.

The workpiece carrier 103 of this embodiment differs from that of the above-described first embodiment in that the support elements 109 of the support member 107 do not include the peripheral recess 119, and in further comprising first and second shim members 171, 172 which are disposed respectively between the positioning member 125 and the cover member 151 and the positioning member 125 and the support member 107, which act to space the spring elements 135 of the positioning elements 129 from the support member 107 and the cover member 151 and thereby facilitate movement of the spring elements 135.

The shim members 171, 172, in this embodiment formed from a sheet body, here a stainless steel sheet, each comprise a plurality of through apertures 173, in this embodiment ten apertures 173 arranged in pairs in a 2×5 array in the same manner as the apertures 111 of the support elements 109 of the support member 107, which allow for workpieces 105 to be loaded into the support elements 109 of the support member 107. The apertures 173 have a slightly larger dimension than the apertures 111 of the support elements 109, such as to extend laterally beyond the spring elements 135 of the positioning elements 129. In other embodiments the shim members 171, 172 could include any number of apertures 173, where having the same configuration as the apertures 111 of the support elements 109 of the support member 107.

In this embodiment the shim members 171, 172, the support member 107, the positioning member 125 and the cover member 151 are configured such that the upper surfaces of the workpieces 105 when loaded onto the support elements 109 of the support member 107 are substantially co-planar with the upper surface of the cover member 151.

The shim members 171, 172 each further comprise a plurality of through slots 181 which are disposed at spaced locations over the surface thereof in correspondence to the engagement slots 121 in the support member 107. The through slots 181 allow for the fixing clips 159 in the cover member 151, which overlies the shim members 171, 172, to pass through to the support member 107, where the fixing clips 159 act to fix the position of the shim members 171, 172 relative to the support member 107 and hold together the support member 107, the positioning member 125, the shim members 171, 172 and the cover member 151 as a unitary structure.

The shim members 171, 172 each further comprise at least two fiducial apertures (not illustrated) which coincide with the at least two fiducials 145 on the positioning member 125, and provide for inspection of the at least two fiducials 145 on the positioning member 125 when aligning the workpiece carrier 103 in a machine.

FIG. 9 illustrates a workpiece carrier loading/unloading assembly 203 in accordance with one embodiment of the present invention for simultaneously loading or unloading a plurality of workpieces 105 into and from one of the above-described workpiece carriers 103.

The workpiece carrier loading/unloading assembly 203 comprises a body unit 205, in this embodiment a base plate, here of rectangular shape, and a plurality of workpiece locating units 207 which are disposed to an upper surface of the body unit 205 in an arrangement corresponding to the arrangement of the support elements 109 of the workpiece carrier 103, in this embodiment in pairs in a 2×5 array, and act simultaneously to locate the workpieces 105 in loading and unloading operations, as will be described in more detail hereinbelow.

The workpiece locating units 207 each comprise a plurality of upstanding pins 211, in this embodiment four pins 211, which are arranged in two pairs at locations corresponding to the respective pairs of passages 117 in the sides of the apertures 111 in the respective support elements 109, and configured to engage the edges of a workpiece 105 at diagonally-opposite corners thereof.

The pins 211 each include a tapered needle 215 at the distal end thereof, an inwardly-facing surface of which acts to guide an edge of a workpiece 105, such that the pins 211 together locate the workpiece 105 when located therebetween, and an outwardly-facing surface of which is operative to engage the resilient arm 139 of the spring element 135 of the positioning element 129 which is disposed thereat, such that the pins 211 act to deflect the spring elements 135 of the positioning element 129 outwardly when the workpiece carrier loading/unloading assembly 203 is raised relative to the workpiece carrier 103 and thereby provide for the engagement and dis-engagement of the workpiece 105 from the spring elements 135 of the positioning element 129.

Operation of the workpiece carrier loading/unloading assembly 203 will now be described with reference to FIGS. 10(a) to (h) of the accompanying drawings.

First, as illustrated in FIGS. 10(a) to (d), workpieces 105 are loaded in a loading operation onto the workpiece carrier 103.

In a first loading step, as illustrated in FIG. 10(a), a workpiece carrier 103 is disposed over the workpiece carrier loading/unloading assembly 203.

In a second loading step, as illustrated in FIG. 10(b), the workpiece carrier loading/unloading assembly 203 is raised relative to the workpiece carrier 103, which causes the pins 211 of each of the workpiece locating units 207 to deflect the spring elements 135 of the respective positioning elements 129 outwardly, in this embodiment through engagement of the tapered needles 215 of the pins 211 against the resilient arms 139 of the spring elements 135. It is to be understood that the raising of the workpiece carrier loading/unloading assembly 203 relative to the workpiece carrier 103 can be achieved by fixing the position of the workpiece carrier 103 and raising the workpiece carrier loading/unloading assembly 203, fixing the position of the workpiece carrier loading/unloading assembly 203 and lowering the workpiece carrier 103 or both raising the workpiece carrier loading/unloading assembly 203 and lowering the workpiece carrier 103.

In a third loading step, as illustrated in FIG. 10(c), workpieces 105 are located between the pins 211 of each of the workpiece locating units 207, and supported by the workpiece supports 115 of the respective support elements 109.

In a fourth loading step, as illustrated in FIG. 10(d), the workpiece carrier loading/unloading assembly 203 is lowered relative to the workpiece carrier 103, which causes the spring elements 135 of each of the positioning elements 129 gradually to return inwardly, in this embodiment through the dis-engagement of the reducing taper of the needles 215 of the pins 211 of each of the workpiece locating units 207 and the resilient arms 139 of the spring elements 135 of the respective positioning elements 129, until such point that the pins 211 of each of the workpiece locating units 207 are dis-engaged from the spring elements 135 of the respective positioning elements 129 and the workpieces 105 are engaged by the spring contacts 137 under the bias of the resilient arms 139 of the spring elements 135. As described hereinabove, as a result of matching the spring force of the spring contacts 135, the workpieces 105 are automatically positioned in the desired position, such that no post-positioning operations are necessary. It is to be understood that the lowering of the workpiece carrier loading/unloading assembly 203 relative to the workpiece carrier 103 can be achieved by fixing the position of the workpiece carrier 103 and lowering the workpiece carrier loading/unloading assembly 203, fixing the position of the workpiece carrier loading/unloading assembly 203 and raising the workpiece carrier 103 or both lowering the workpiece carrier loading/unloading assembly 203 and raising the workpiece carrier 103.

Following this loading operation, the workpiece carrier 103 having the workpieces 105 loaded thereon is ready for operation in a machine, either in situ or ex situ, and the machine operation requires a single alignment operation of the workpiece carrier 103, through the use of the fiducials 145, and no individual alignment of each of the respective workpieces 105.

Following operation in the machine, an unloading operation, as illustrated in FIGS. 10(e) to (h), is performed in order to unload the workpieces 105 from the workpiece carrier 103.

In a first unloading step, as illustrated in FIG. 10(e), the workpiece carrier 103 is disposed over the workpiece carrier loading/unloading assembly 203.

In a second unloading step, as illustrated in FIG. 10(f), the workpiece carrier loading/unloading assembly 203 is raised relative to the workpiece carrier 103, which causes the pins 211 of each of the workpiece locating units 207 to deflect the spring elements 135 of the respective positioning elements 129 outwardly, in this embodiment through engagement of the needles 215 of the pins 211 and the resilient arms 139 of the spring elements 135, such as to release the spring elements 135 of the positioning elements 129 from the respective workpieces 105 and locate the workpieces 105 between the pins 211 of each of the respective workpiece locating units 207. It is to be understood that the raising of the workpiece carrier loading/unloading assembly 203 relative to the workpiece carrier 103 can be achieved by fixing the position of the workpiece carrier 103 and raising the workpiece carrier loading/unloading assembly 203, fixing the position of the workpiece carrier loading/unloading assembly 203 and lowering the workpiece carrier 103 or both raising the workpiece carrier loading/unloading assembly 203 and lowering the workpiece carrier 103.

In a third unloading step, as illustrated in FIG. 10(g), workpieces 105 are unloaded from the workpiece carrier 103.

In a fourth unloading step, as illustrated in FIG. 10(h), the workpiece carrier loading/unloading assembly 203 is lowered relative to the workpiece carrier 103, which causes the spring elements 135 of each of the positioning elements 129 gradually to return inwardly, in this embodiment through the dis-engagement of the reducing taper of the needles 215 of the pins 211 of each of the workpiece locating units 207 and the resilient arms 139 of the spring elements 135 of the respective positioning elements 129, until such point that the pins 211 of each of the workpiece locating units 207 are dis-engaged from the spring elements 135 of the respective positioning elements 129 and the spring elements 135 are in the rest configuration. It is to be understood that the lowering of the workpiece carrier loading/unloading assembly 203 relative to the workpiece carrier 103 can be achieved by fixing the position of the workpiece carrier 103 and lowering the workpiece carrier loading/unloading assembly 203, fixing the position of the workpiece carrier loading/unloading assembly 203 and raising the workpiece carrier 103 or both lowering the workpiece carrier loading/unloading assembly 203 and raising the workpiece carrier 103.

FIGS. 11 to 13 illustrate a workpiece carrier 303 in accordance with a fourth embodiment of the present invention which provides for the precise and automatic individual positioning of a plurality of workpieces 305 when loaded thereon, without requiring any subsequent positioning operations, typically to enable operation by a machine, such as a printing, deposition or placement machine.

For the purposes of illustration, the workpiece carrier 303 is illustrated only partially filled with workpieces 305. Examples of workpieces 305 include the bases of packages, such as ball grid array (BGA) and pin grid array (PGA) substrates, which house integrated circuits, such as microprocessors, and substrates, such as printed circuit boards, onto which electronic components are mounted.

The workpiece carrier 303 comprises a lower, support member 307, in this embodiment a plate, which includes a plurality of workpiece support elements 309, in this embodiment ten support elements 309 arranged in pairs in a 2×5 array, for supporting respective ones of the workpieces 305. In other embodiments the support member 307 could include any number of support elements 309, which could be arranged in any configuration and have any shape.

In this embodiment the support member 307 is formed of a synthetic material, such as a plastics material or a re-inforced plastics material, and can be machined or moulded. In another embodiment the support member 307 could be formed of a metal.

The support elements 309 each comprise a through aperture 311, in this embodiment a substantially square aperture, and a plurality of workpiece supports 315 which are disposed about the periphery of the aperture 311, in this embodiment four workpiece supports 315 which are disposed at the respective corners of the aperture 311, here integrally formed at the respective corners of the aperture 311, for supporting the respective corners of a workpiece 305.

The support elements 309 each further comprise a plurality of passages 317, in this embodiment through holes, which are located at the respective sides thereof, in this embodiment two passages 317 which are located adjacent the respective corners of one pair of diagonally-opposite corners of the aperture 311. As will be described in more detail hereinbelow, the passages 317 allow for the introduction of tooling in order to effect the loading and unloading of a workpiece 305 into and from the support element 309.

The support elements 309 each further comprise a spacer 319 which is located at the upper edge of the aperture 311, such that a positioning member 325, which, as will be described in more detail hereinbelow, is disposed above the support member 307, is spaced from the support member 307 about the aperture 311.

In this embodiment the spacer 319 comprises first and spacer sections 320a, 320b, here elongate sections, which are disposed to opposite sides of the aperture 311. In this embodiment the spacer sections 320a, 320b are integrally formed as part of the support member 307.

The support member 307 further comprises a plurality of, in this embodiment four engagement recesses 321 which are disposed at spaced locations therein, in this embodiment at opposite ends of the support member 307. As will be described in more detail hereinbelow, the engagement recesses 321 receive fixing elements 347 which are formed in a positioning member 325 and act to hold together the support member 307 and the positioning member 325 as a unitary structure.

The workpiece carrier 303 further comprises a positioning member 325, in this embodiment formed of a sheet body, which is disposed above the support member 307 and includes a plurality of positioning elements 329, in this embodiment ten positioning elements 329 arranged in pairs in a 2×5 array and having the same configuration as the support elements 309 of the support member 307, which act automatically, precisely and individually to position respective ones of the workpieces 305 in relation to the respective support elements 309. In other embodiments the positioning member 325 could include any number of positioning elements 329, where having the same configuration and shape as the support elements 309 of the support member 307.

The positioning elements 329 each comprise a through aperture 331, in this embodiment a substantially square aperture, which has the same shape as the aperture 311 of the respective support element 309, and a plurality of spring elements 335 which are disposed about the periphery of the aperture 331 such as to engage a workpiece 305, in this embodiment four spring elements 335 which are configured to engage a workpiece 305 at two pairs of locations adjacent the respective corners of the one pair of diagonally-opposite corners of the aperture 311 of the respective support element 309, such as to provide for the automatic positioning of a workpiece 305 when loaded onto the support element 309 of the support member 307.

In this embodiment the spring elements 335 each comprise a spring contact 337, which laterally engages a respective side of the workpiece 305, in this embodiment adjacent a respective one of a pair of diagonally-opposite corners of the workpiece 305, and a resilient arm 339 which resiliently connects the spring contact 337 to the body of the positioning member 325, such as to bias the spring contact 337 inwardly relative to the aperture 331 of the positioning element 329.

In this embodiment the spring contact 337 has a workpiece-contact face 341, here an inwardly-facing, flat face, which laterally engages a respective side of the workpiece 305, and a tooling-contact face 343, which is configured to be engaged by a tooling element 411, as will be described in more detail hereinbelow. In an alternative embodiment the workpiece-contact face 341 could be an arcuate face.

In this embodiment the tooling-contact faces 343 of the spring contacts 337 of each of the adjacent pairs of spring elements 335 are in mutually-opposed relation and define a tooling aperture 345 therebetween, here a narrow slot, which is configured to receive a tooling element 411, here a single tooling element 411, such that the single tooling element 411 is operative to deflect the pair of spring elements 335 in order to effect the loading and unloading of workpieces 305 into and from the respective support element 309. With this configuration, the loading and unloading of workpieces 305 into and from a support element 309 is achieved with only a pair of tooling elements 411.

In this embodiment each resilient arm 339 extends from a location adjacent the adjacent corner of the aperture 331 of the positioning element 329 to which the respective spring contact 337 is disposed and substantially parallel to the respective side of the aperture 331.

With this configuration, the spring elements 335 are deflectable outwardly relative to the aperture 331 of the respective positioning element 329 by tooling, as will be described in more detail hereinbelow, to allow for the loading of a workpiece 305 into the positioning element 329, and, on removal of the tooling, the resilience of the arms 339 acts to bias the spring contacts 337 inwardly, such as automatically and individually precisely to position the loaded workpiece 305, without requiring any subsequent positioning operation.

The positioning member 325 further comprises a plurality of, in this embodiment four fixing clips 347, in this embodiment snap clips, which are disposed at spaced locations therein in correspondence to the engagement recesses 321 in the support member 307, and act to engage the engagement recesses 321 in the support member 307, such as to hold together the support member 307 and the positioning member 325 as a unitary structure and also fix the position of the positioning member 325 relative to the support member 307.

In this embodiment the use of fixing clips 347 as the means of fixing together the components of the workpiece carrier 303 advantageously allows for quick and easy assembly and dis-assembly, in the event that modification or repair is required. In other embodiments, other means of fixing could be employed, such as adhesive bonding, spot-welding and riveting.

In this embodiment the spring elements 335 are precision formed, typically by laser cutting or chemical milling, such as to have a precise and predetermined spatial arrangement, and also to ensure that the spring force of the spring elements 335 is matched, such as to ensure that the workpieces 305 are precisely positioned.

In this embodiment the sheet body of the positioning member 325 is formed of a spring steel, but could be formed of any other material which provides the spring elements 335 with the necessary characteristics which provide for the repeated accurate positioning of the supported workpieces 305.

The positioning member 325 further comprises at least two fiducials 349, which enable the alignment of the workpiece carrier 303 when mounted in a machine. As the workpieces 305 which are mounted in the workpiece carrier 303 are automatically and individually pre-positioned by the respective positioning elements 329, it is only necessary to align the workpiece carrier 303.

FIG. 14 illustrates a workpiece carrier loading/unloading assembly 403 in accordance with another embodiment of the present invention for loading or unloading a plurality of workpieces 305 into and from one of the above-described workpiece carriers 303.

The workpiece carrier loading/unloading assembly 403 comprises a body unit 405, in this embodiment a box section, here of rectangular shape, a plurality of positioning elements 406 which act to fix the position of a workpiece carrier 303 when mounted on the body unit 405, a plurality of actuator units 407 which are disposed to an upper surface of the body unit 405 in an arrangement corresponding to the arrangement of the support elements 309 of the workpiece carrier 303, in this embodiment in pairs in a 2×5 array, and are operable to allow for loading and unloading of workpieces 305 into and from the support elements 309 of the workpiece carrier 303 in loading and unloading operations, as will be described in more detail hereinbelow.

The actuator units 407 each comprise at least one, in this embodiment a plurality of upstanding actuator pins 411, here two actuator pins 411, which are arranged in correspondence with the tooling apertures 345 between the tooling-contact faces 343 of the spring contacts 337 of each of the adjacent pairs of spring elements 335 of a respective one of the support elements 309, such that, when the workpiece carrier 303 is mounted on the body unit 405, the actuator pins 411 extend through respective ones of the tooling apertures 345.

The actuator pins 411 each comprise a body section 413 which is rotatably coupled to the body unit 405, in this embodiment about a vertical axis, and an actuator section 415, in this embodiment a flat blade, which is configured to extend into the respective tooling aperture 345 as defined between the tooling-contact faces 343 of the spring contacts 337 of adjacent pairs of spring elements 335. As will be described in more detail hereinbelow, the actuator pins 411 are rotatable between a first, rest configuration, as illustrated, for example, in FIG. 16(b), in which the workpiece carrier 303 can be mounted onto the body unit 405, and a second, actuated configuration, as illustrated, for example, in FIG. 16(c), in which the actuator sections 415 of the actuator pins 411, here the oppositely-directed faces of the blade sections, engage the tooling-contact faces 343 of the adjacent spring contacts 337 and bias the spring contacts 337 outwardly to allow for the loading and unloading of workpieces 305 into and from the support units 309.

The workpiece carrier loading/unloading assembly 403 further comprises an actuator member 421, in this embodiment a lever, which is operatively coupled to each of the actuator pins 411, in this embodiment by a linkage assembly (not illustrated), between a first, rest position, in which the actuator pins 411 are in the rest configuration to allow for the loading and unloading of the workpiece carrier 303 to and from the body unit 405 and an actuated configuration, in which the actuator pins 411 are rotated to the actuated configuration in which the actuator sections 415 of the actuator pins 411, here the oppositely-directed faces of the blade sections, engage the tooling-contact faces 343 of the adjacent spring contacts 337 and bias the spring contacts 337 outwardly to allow for the loading and unloading of workpieces 305 into and from the support units 309.

Operation of the workpiece carrier loading/unloading assembly 403 will now be described with reference to FIGS. 16(a) to (l) of the accompanying drawings.

First, as illustrated in FIGS. 16(a) to (f), workpieces 305 are loaded in a loading operation onto the workpiece carrier 303.

In a first loading step, as illustrated in FIG. 16(a), a workpiece carrier 303 is disposed over the workpiece carrier loading/unloading assembly 403.

In a second loading step, as illustrated in FIG. 16(b), with the actuator member 421 of the workpiece carrier loading/unloading assembly 403 de-actuated, in this embodiment in the rest position, the workpiece carrier 303 is loaded onto the workpiece carrier loading/unloading assembly 403, which causes the actuator pins 411 of each of the actuator units 407 to pass into the tooling apertures 345 between the tooling-contact faces 343 of the spring contacts 337 of each of the adjacent pairs of spring elements 335. It is to be understood that loading of the workpiece carrier loading/unloading assembly 403 can be achieved by fixing the position of the workpiece carrier 303 and raising the workpiece carrier loading/unloading assembly 403, fixing the position of the workpiece carrier loading/unloading assembly 403 and lowering the workpiece carrier 303 or both raising the workpiece carrier loading/unloading assembly 403 and lowering the workpiece carrier 303.

In a third loading step, as illustrated in FIG. 16(c), the actuator member 421 of the workpiece carrier loading/unloading assembly 403 is actuated, in this embodiment by moving the same to the actuated position, which causes the actuator sections 415 of the actuator pins 411, here the oppositely-directed faces of the blade sections, to engage the tooling-contact faces 343 of the adjacent spring contacts 337 and bias the spring contacts 337, and the workpiece-contact faces 341 thereof, outwardly to allow for the loading of workpieces 305 into the support units 309.

In a fourth loading step, as illustrated in FIG. 16(d), workpieces 305 are loaded into the support units 309 as required.

In a fifth loading step, as illustrated in FIG. 16(e), the actuator member 421 of the workpiece carrier loading/unloading assembly 403 is de-actuated, in this embodiment by returning the same to the rest position, which causes the spring elements 335 of each of the positioning elements 329 gradually to return inwardly, in this embodiment through dis-engagement of the actuator sections 415 of the actuator pins 411, here the oppositely-directed faces of the blade sections, from the tooling-contact faces 343 of the adjacent spring contacts 337, until such point that the actuator pins 411 of each of the workpiece locating units 407 are dis-engaged from the spring elements 335 and the workpieces 305 are laterally engaged by the spring contacts 337 under the bias of the resilient arms 339 of the spring elements 335. As described hereinabove, as a result of matching the spring force of the spring contacts 335, the workpieces 305 are automatically positioned in the desired position, such that no post-positioning operations are necessary.

In a final step, as illustrated in FIG. 16(f), the workpiece carrier 303 is removed from the workpiece carrier loading/unloading assembly 403.

Following this loading operation, the workpiece carrier 303 having the workpieces 305 loaded thereon is ready for operation in a machine, either in situ or ex situ, and the machine operation requires a single alignment operation of the workpiece carrier 303, through the use of the fiducials 349, and no individual alignment of each of the respective workpieces 305.

Following operation in the machine, an unloading operation, as illustrated in FIGS. 16(g) to (l), is performed in order to unload the workpieces 305 from the workpiece carrier 303.

In a first unloading step, as illustrated in FIG. 16(g), the workpiece carrier 303 is disposed over the workpiece carrier loading/unloading assembly 403.

In a second unloading step, as illustrated in FIG. 16(h), with the actuator member 421 of the workpiece carrier loading/unloading assembly 403 de-actuated, in this embodiment in the rest position, the workpiece carrier 303 is located on the workpiece carrier loading/unloading assembly 403, which causes the actuator pins 411 of each of the actuator units 407 to pass into the tooling apertures 345 between the tooling-contact faces 343 of the spring contacts 337 of each of the adjacent pairs of spring elements 335. It is to be understood that loading of the workpiece carrier 303 on the workpiece carrier loading/unloading assembly 403 can be achieved by fixing the position of the workpiece carrier 303 and raising the workpiece carrier loading/unloading assembly 403, fixing the position of the workpiece carrier loading/unloading assembly 403 and lowering the workpiece carrier 303 or both raising the workpiece carrier loading/unloading assembly 403 and lowering the workpiece carrier 303.

In a third unloading step, as illustrated in FIG. 16(i), the actuator member 421 of the workpiece carrier loading/unloading assembly 403 is actuated, in this embodiment by moving the same to the actuated position, which causes the actuator sections 415 of the actuator pins 411, here the oppositely-directed faces of the blade sections, to engage the tooling-contact faces 343 of the adjacent spring contacts 337 and bias the spring contacts 337, and the workpiece-contact faces 341 thereof, outwardly to allow for the unloading of workpieces 305 from the support units 309.

In a fourth unloading step, as illustrated in FIG. 16(j), workpieces 305 are unloaded from the workpiece carrier 303.

In a fifth unloading step, as illustrated in FIG. 16(k), the actuator member 421 of the workpiece carrier loading/unloading assembly 403 is de-actuated, in this embodiment by returning the same to the rest position, which causes the spring elements 335 of each of the positioning elements 329 gradually to return inwardly, in this embodiment through dis-engagement of the actuator sections 415 of the actuator pins 411, here the oppositely-directed faces of the blade sections, from the tooling-contact faces 343 of the adjacent spring contacts 337, until such point that the actuator pins 411 of each of the workpiece locating units 407 are dis-engaged from the spring elements 335 and the spring elements 335 are in the rest configuration.

In a final step, as illustrated in FIG. 16(l), the workpiece carrier 303 is removed from the workpiece carrier loading/unloading assembly 403.

Finally, it will be understood that the present invention has been described in its preferred embodiments and can be modified in many different ways without departing from the scope of the invention as defined by the appended claims.

1. A workpiece carrier for supporting a plurality of workpieces, the workpiece carrier comprising:
a plurality of support elements, each for supporting a workpiece; and
a plurality of positioning elements, each associated with a respective one of the support elements and being operative to position a workpiece at a predetermined position in the respective support element, wherein the positioning elements each comprise a plurality of biasing elements which are disposed in opposed relation and configured laterally to bias the workpiece and position the workpiece at the predetermined position.

2. The workpiece carrier of claim 1, wherein the positioning elements are each configured automatically to position a workpiece at the predetermined position in the respective support element when loaded thereinto, without requiring any subsequent positioning operations.

3. The workpiece carrier of claim 1, wherein the positioning elements are each configured such that workpieces are repeatedly positioned at the predetermined position when loaded into the respective support element.

4. The workpiece carrier of claim 1, wherein the biasing elements are configured laterally to engage opposite edges of a workpiece and apply an inwardly-directed biasing force thereto.

5. The workpiece carrier of claim 4, wherein the positioning elements each comprise first and second pairs of biasing elements which are configured laterally to engage opposite edges of a workpiece.

6. The workpiece carrier of claim 1, wherein the support elements each comprise a plurality of workpiece supports on which a workpiece is supported.

7. The workpiece carrier of claim 6, wherein the support elements each comprise a through aperture and the plurality of workpiece supports disposed thereabout.

8. The workpiece carrier of claim 7, wherein the through aperture is rectangular in shape and the workpiece supports are disposed at the respective corners of the through aperture.

9. The workpiece carrier of claim 1, wherein the biasing elements have matched biasing forces.

10. The workpiece carrier of claim 1, wherein the biasing elements comprise spring elements.

11. The workpiece carrier of claim 10, wherein the spring elements each comprise a spring contact for engaging a workpiece when supported on the respective support element and a spring arm which is operative resiliency to bias the spring contact laterally.

12. The workpiece carrier of claim 11, wherein the spring arm is operative to bias the spring contact laterally inwardly into engagement with a workpiece when supported on the respective support element.

13. The workpiece carrier of claim 11, wherein the spring contact has an arcuate contact face.

14. The workpiece carrier of claim 4, wherein the workpieces are substantially rectangular, and the positioning elements comprise first and second pairs of biasing elements which are configured laterally to engage a workpiece at two pairs of spaced locations adjacent diagonally-opposite corners of the workpiece.

15. The workpiece carrier of claim 14, wherein the biasing elements have matched biasing forces.

16. The workpiece carrier of claim 14, wherein the biasing elements comprise spring elements.

17. The workpiece carrier of claim 16, wherein the spring elements are deflectable outwardly, such as to allow for loading and unloading of workpieces into and from the respective support element.

18. The workpiece carrier of claim 17, wherein the spring elements each comprise a spring contact, which includes a workpiece-contact face for laterally engaging a respective edge of a workpiece, and a spring arm which is operative resiliently to bias the spring contact laterally inwardly into engagement with a workpiece when supported on the respective support element.

19. The workpiece carrier of claim 18, wherein the workpiece-contact face is an arcuate contact face.

20. The workpiece carrier of claim 18, wherein the spring contact includes a tooling-contact face which is configured to be engaged by a tooling element in loading and unloading a workpiece into and from the respective support element.

21-133. (canceled)
